(19) United States
(12) Patent Application Publication
(10) Pub. No.: US 2013/0191055 A1
(43) Pub. Date: Jul. 25, 2013

(54) APPARATUS AND SYSTEM FOR MANAGING MULTIPLE ELECTRONIC DEVICES

(71) Applicant: Akira ITOGAWA, Kanagawa (JP)

(72) Inventor: Akira ITOGAWA, Kanagawa (JP)

(73) Assignee: RICOH COMPANY, LTD., Tokyo (JP)

(21) Appl. No.: 13/743,519

(22) Filed: Jan. 17, 2013

(30) Foreign Application Priority Data
Jan. 20, 2012 (JP) 2012-009940
Oct. 23, 2012 (JP) 2012-234112

(51) Int. Cl. G01R 21/00; G06F 17/00

(52) U.S. Cl. CPC G01R 21/00; G06F 17/00
USPC 702/61

(57) ABSTRACT

A management apparatus includes an obtaining part configured to obtain a first log data of a first electronic device that is capable of transmitting the first log data, a generating part configured to generate a second log data of a second electronic device that is unable to transmit the second log data, a calculating part configured to calculate a first power consumption amount consumed when the first and second electronic devices are used during a predetermined period, and an outputting part configured to output the power consumption amount calculated by the calculating part.

### BACKGROUND OF THE INVENTION

1. Field of the Invention

The present invention relates to a technology for managing multiple electronic devices.

2. Description of the Related Art

In recent years and continuing, there is a growing demand for technology that reduces costs related to the use of electronic devices in an office environment or the like in view of factors such as unsteady supply of power due to natural disasters and environmental awareness.

For example, Japanese Laid-Open Patent Publication No. 2010-097391 discloses a technology that compares device data obtained from an electronic device (e.g., image processing apparatus) with pre-obtained cost data pertaining to a substitute device(s) and identifies, based on the comparison, a suitable substitute device that reduces costs related to the use of the electronic device if the electronic device is substituted with the identified substitute device. With this technology, a cost reducing substitute device can be proposed to the user.

However, a conventional method may not be able to sufficiently provide services desired by the user. With the conventional method, device data transmitted from a particular electronic device is used in deciding the electronic device to be used in a user environment (e.g., office). However, from a standpoint of operating one or more electronic devices in the user environment, the use of device data from merely a single particular electronic device may be insufficient for the user. That is, in order to achieve cost reduction, it is desired to consider the effective measures (matters to be improved) to be taken in view of the entire user environment. For example, in order to reduce power consumption of one or more electronic devices, it is desired to grasp how the electronic devices are being used in the entire user environment (how much power is being used in the entire user environment), so that the total value of power consumption of the electronic devices in the user environment is maintained less than or equal to a predetermined value.

### SUMMARY OF THE INVENTION

The present invention may provide an apparatus and a system for managing multiple electronic devices that substantially obviate one or more of the problems caused by the limitations and disadvantages of the related art.

Features and advantages of the present invention are set forth in the description which follows, and in part will become apparent from the description and the accompanying drawings, or may be learned by practice of the invention according to the teachings provided in the description. Objects as well as other features and advantages of the present invention will be realized and attained by an apparatus and a system for managing multiple electronic devices particularly pointed out in the specification in such full, clear, concise, and exact terms as to enable a person having ordinary skill in the art to practice the invention.

To achieve these and other advantages and in accordance with the purpose of the invention, as embodied and broadly described herein, an embodiment of the present invention provides a management apparatus including an obtaining part configured to obtain a first log data of a first electronic device that is capable of transmitting the first log data, a generating part configured to generate a second log data of a second electronic device that is unable to transmit the second log data, a calculating part configured to calculate a first power consumption amount consumed when the first and second electronic devices are used during a predetermined period, and an outputting part configured to output the power consumption amount calculated by the calculating part.

Other objects, features and advantages of the present invention will become more apparent from the following detailed description when read in conjunction with the accompanying drawings.

### BRIEF DESCRIPTION OF THE DRAWINGS

FIG. 1 is a schematic diagram illustrating an example of a configuration of a management system according to an embodiment of the present invention;

FIG. 2 is a schematic diagram illustrating a hardware configuration of a management apparatus according to an embodiment of the present invention;

FIG. 3 is a schematic diagram illustrating a configuration of a management function of a management apparatus according to an embodiment of the present invention;

FIG. 4 is a schematic diagram illustrating an example of a configuration of a log generating unit according to an embodiment of the present invention;

FIGS. 5A and 5B illustrate a configuration of device management data according to an embodiment of the present invention;

FIG. 6 is a schematic diagram illustrating a configuration of log management data according to an embodiment of the present invention;

FIG. 7 is a schematic diagram illustrating a configuration of power consumption management data (example 1) according to an embodiment of the present invention;

FIG. 8 is a schematic diagram illustrating an operation of generating a report according to an embodiment of the present invention;

FIG. 9 is a flowchart illustrating procedures of a log obtaining process according to an embodiment of the present invention;

FIG. 10 is a flowchart illustrating procedures of a log generating process according to an embodiment of the present invention;

FIG. 11 is a flowchart illustrating procedures of a report generating process according to an embodiment of the present invention;

FIG. 12 is a flowchart illustrating an example of a process of generating intermediate data of a device operation according to an embodiment of the present invention;

FIG. 13 is a flowchart illustrating an example of a process of generating intermediate data of the device status according to an embodiment of the present invention;

FIG. 14 is a flowchart illustrating an example of a subsequent process according to an embodiment of the present invention;

FIG. 15 is a schematic diagram illustrating a configuration of intermediate data of the use of a currently used electronic device according to an embodiment of the present invention;

FIG. 16 is a flowchart illustrating an example of the process of generating a report according to an embodiment of the present invention;

FIG. 17 is a schematic diagram illustrating an example where intermediate data of the use of a currently used electronic device is sorted into groups according to an embodiment of the present invention;

FIGS. 18A and 18B are schematic diagrams illustrating examples of data of a report of the use of a currently used electronic device according to an embodiment of the present invention;

FIG. 19 is a flowchart illustrating procedures of a simulation process according to an embodiment of the present invention;

FIG. 20 is a schematic diagram illustrating a configuration of power consumption management data (example 2) according to an embodiment of the present invention;

FIG. 21 is a schematic diagram illustrating a configuration of simulation log management data according to an embodiment of the present invention;

FIG. 22 is a schematic diagram illustrating a configuration of simulation intermediate data according to an embodiment of the present invention;

FIGS. 23A and 23B are schematic diagram illustrating examples of data of a report before and after substitution according to an embodiment of the present invention;

FIG. 24 is a schematic diagram illustrating an example of a configuration of a management system according to the modified example 1;

FIG. 25 is a schematic diagram illustrating a hardware configuration of the log generating apparatus according to an embodiment of the present invention;

FIG. 26 is a schematic diagram illustrating a configuration for executing a management function according to the modified example 1;

FIG. 27 is a schematic diagram illustrating a configuration of a log generating unit according to the modified example 1;

FIG. 28 is a schematic diagram illustrating an example of a configuration of a management system according to the modified example 2;

FIG. 29 is a schematic diagram illustrating a configuration for executing a management function according to the modified example 2; and

FIG. 30 is a schematic diagram illustrating a modified example of a configuration for executing a management function according to an embodiment of the present invention.

### DETAILED DESCRIPTION OF THE PREFERRED EMBODIMENTS

Embodiments of the present invention are described with reference to the attached drawings.

### First Embodiment

### <System Configuration>

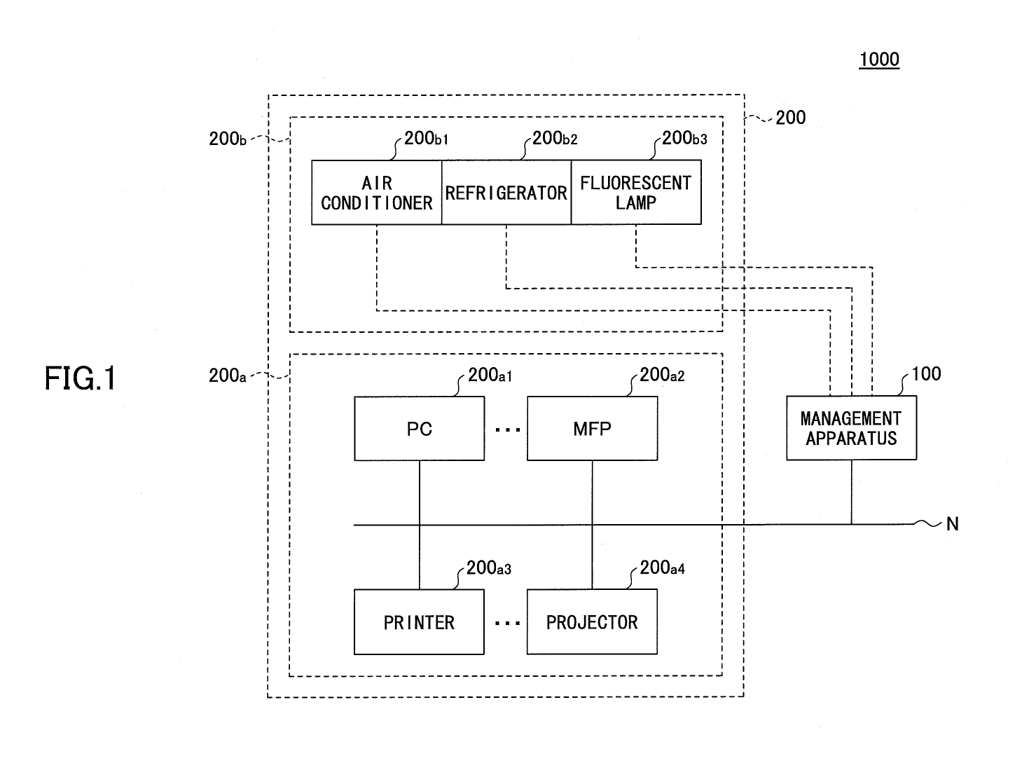

FIG. 1 is a schematic diagram illustrating an example of a configuration of a management system 1000 according to an embodiment of the present invention. The configuration of the system 1000 of FIG. 1 has one or more electronic devices 200a, 200b (hereinafter also collectively referred to as “electronic device 200”) and a management apparatus 100 that are connected to each other by a data transfer path N (e.g., LAN (Local Area Network).

The electronic device 200 has a function of executing an operation in accordance with a request from the user or the like. That is, the electronic device 200 executes a requested function by performing a predetermined process. In this embodiment, the environment of the user (user environment) is a typical office environment. Therefore, the electronic device 200 can be categorized into an electronic device 200a capable of notifying (transmitting) a status/operation log (history data) pertaining to the electronic device 200a by the electronic device 200a itself and an electronic device 200b unable to notify (transmit) a status/operation log (history data) pertaining to the electronic device 200b by the electronic device 200b itself. The electronic device 200a may be, for example, a data processing apparatus (data terminal) including a PC (Personal Computer) 200a1 or an image processing apparatus including a MFP (Multifunction Peripheral) 200a2, a printer 200a3, a projector 200a4. The electronic device 200b may be, for example, a household electronic device such as an air condition apparatus (e.g., air conditioner) 200b1 or a refrigerator 200b2. The electronic device 200b may also be, for example, an illumination apparatus (e.g., fluorescent lamp 200b3). In this embodiment, the one or more electronic devices 200 are devices that are subject to cost management by the management system 1000.

The data processing apparatus 200a1 is not limited to a PC but may also be a smart device (e.g., smart phone, a tablet type terminal). That is, other electronic devices may be used as the data processing apparatus 200a1 as long as they can communicate with the management apparatus 100.

The management apparatus 100 is a server apparatus having a function of managing the electronic device 200. The management apparatus 100 records (stores) the status/operation log of the electronic device 200 and manages the electronic device 200 based on the status/operation log recorded therein. Further, the management apparatus 100 calculates the amount of electric power consumed (power consumption amount) within a predetermined period by the electronic device 200 currently used in the management system 1000 (current status value) and the amount of power estimated to be consumed (estimated power consumption amount) within a predetermined period by a substitute device to be used in the management system 1000 (estimate value). The management apparatus also processes (transforms) the calculated values (including the total value of the power consumption amount before substitution with the substitute device and the power consumption amount after the substitution with the substitute device) into visible comparable data and provides the processed data, so that the user can utilize the processed data.

In the following, the power consumption amount consumed within the predetermined period by the currently used electronic device 200 is explained as a power consumption consumed within a predetermined period by currently used first and second electronic devices. Likewise, the estimated power consumption amount estimated to be consumed within the predetermined period by the substitute device is explained as an estimated power consumption amount estimated to be consumed within a predetermined period in a case where a first or a second electronic device is substituted with another first or second electronic device.

The management system 1000 uses the above-described electronic device 200 and the management apparatus 100 to provide the following service.

The management apparatus 100 records a status/operation log of the electronic device 200 in a predetermined storage area. In a case where the electronic device 200 is the electronic device 200a, the management apparatus 100 stores log data received from the electronic device 200a. In a case where the electronic device 200 is the electronic device 200b, the management apparatus 100 confirms the status/operation of the electronic device 200b. In a case where the management apparatus 100 confirms a change in the status/operation of the electronic device 200b, the management apparatus 100 generates log data corresponding to the change and stores the generated log data therein.

Then, in a case where the management apparatus 100 accepts an input (designation) of a report period (input period data) by way of a predetermined interface, the management apparatus 100 calculates the power consumption amount (current status value) of the currently used electronic device (target electronic device) 200 during the report period (designated period). Further, in a case where the management apparatus 100 accepts an input (designation) of a substitute electronic device 200 capable of attaining a device status recorded in a log or capable of executing a device operation recorded in a log, the management apparatus 100 performs the following processes. That is, the management apparatus 100 estimates (simulates) a case of substituting a target electronic device 200 with a substitute electronic device 200 capable of achieving a device status recorded in a log or capable of executing a device operation recorded in a log and achieving the device status or executing the device operation with the substitute electronic device 200 instead of using the target electronic device 200. The management apparatus 100 calculates, based on the results of the estimation (simulation), an estimated power consumption amount in a case where the substitute device is used within the report period (estimate value).

As a result, the management apparatus 100 generates a visually comparable report that allows comparison between the power consumption amount of the use of the currently used electronic device 200 during the report period and the estimated power consumption amount of the use of the substitute electronic device 200 during the report period in the entire user system. Accordingly, the generated report can be displayed on a screen of, for example, the user's PC (data terminal) 200a1 in response to a request from the user's PC 200a1.

Further, accordingly, the management system 1000 having the above-described configuration can provide a service of visualizing an optimum proposal for achieving cost reduction in view of the use of the electronic device 200 in the entire management system 1000.

### <Hardware Configuration>

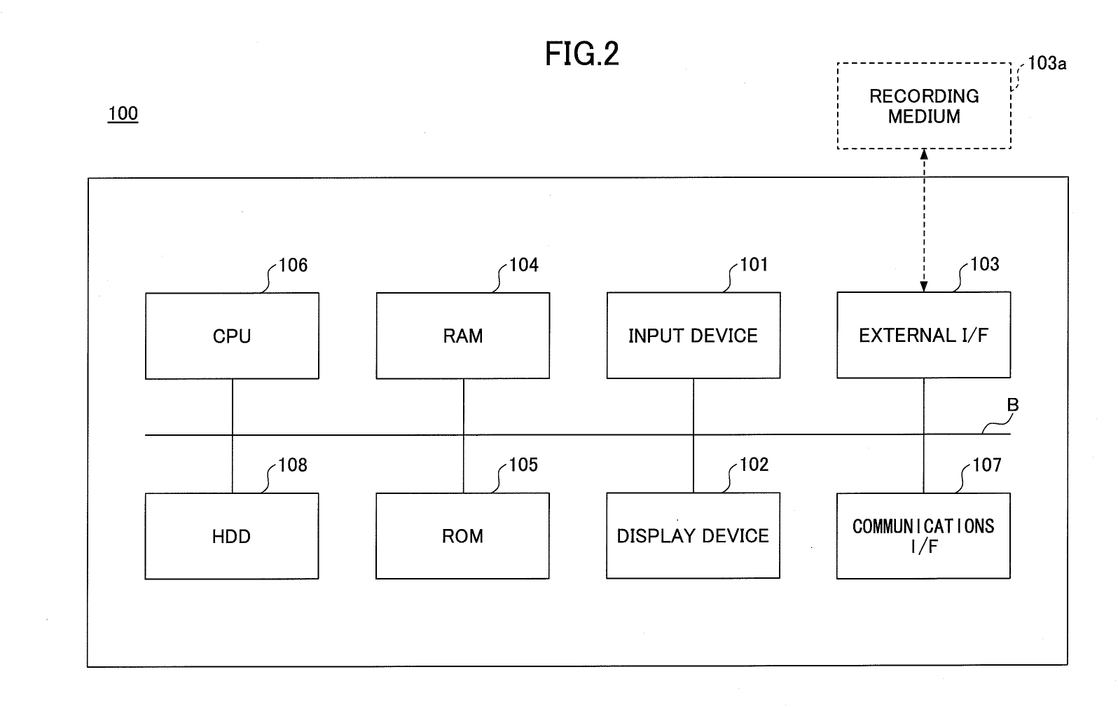

FIG. 2 is a schematic diagram illustrating a hardware configuration of the management apparatus 100 according to an embodiment of the present invention. As illustrated in FIG. 2, the management apparatus 100 includes, for example, an input device 101, a display device 102, an external interface (I/F) 103, a RAM (Random Access Memory) 104, a ROM (Read Only Memory) 105, a CPU (Central Processing Unit) 106, a communications I/F 107, and a HDD (Hard Disk Drive) 108 that are connected with each other by a bus B.

The input device 101 includes, for example, a keyboard and/or a mouse for inputting control signals to the management apparatus 100. The display device 102 includes, for example, a display for displaying the results of processes performed by the management apparatus 100.

The communications I/F 107 is an interface that connects the management apparatus 100 to a network. Thus, the management apparatus 100 can perform data communications with other devices (including electronic devices having a communication function) via the communications I/F 107.

The HDD 108 is a non-volatile storage device that stores programs and data therein. The programs and data stored in the HDD 108 may be, for example, basic software for controlling the entire management apparatus 100 (e.g., OS (Operating System)) and application software for providing various functions to the OS. The HDD 108 manages the programs and data with a predetermined file system and/or a database (DB).

The external I/F 103 is an interface between the management apparatus 100 and an external device. The external device may be, for example, a computer-readable-recording medium 103a. Thereby, the management apparatus 100 can read data from and/or write data to the recording medium 103a via the external I/F 103. The recording medium 103a includes, for example, a floppy disk (trademark), a compact disk (CD), a DVD (Digital Versatile Disk), a SD (Secure Digital) memory card, and a USB (Universal Serial Bus) memory.

The ROM 105 is a non-volatile memory (storage device) capable of storing data therein even in a state where power is switched off. The ROM 105 may store programs and data such as BIOS (Basic Input/Output System) data used when activating the management apparatus 100, OS setting data, and network setting data. The RAM 104 is a volatile memory (storage device) that temporarily stores programs and data therein. The CPU 106 is an operation device that controls and executes the entire functions of the management apparatus 100 by loading a program or data to the RAM 104 and executing the loaded program or data.

Accordingly, the management apparatus 100 having the above-described hardware configuration can provide various data processing services including a cost reduction process (power consumption management process).

### <Management Function>

Next, a management function according to an embodiment of the present invention is described.

As described above, the management apparatus 100 according to an embodiment of the present invention stores status/operation data of the electronic device 200 in a predetermined storage area. The management apparatus 100 calculates the power consumption amount (current status value) of the currently used electronic device during a predetermined period based on the stored status/operation data. Further, the management apparatus 100 estimates (simulates) a case where a substitute device is used to attain a device status or execute an operation of a substituted electronic device. Then, the management apparatus 100 calculates, based on the results of the estimation (simulation), an estimated power consumption amount in a case where the substitute device is used within the predetermined period (estimate value). As a result, the management apparatus 100 generates a visually comparable report that allows the power consumption amount of the current use of the electronic device (in the entire system) during the predetermined period to be compared with the estimated power consumption amount of the use of the substitute device during the predetermined period. In other words, the management apparatus 100 generates a visually comparable report allowing comparison between the value of the power consumption amount before substitution with the substitute device and the value of the power consumption amount after the substitution with the substitute device. Accordingly, the generated report can be provided to the user. Hence, the management apparatus 100 can provide a function of managing the electronic device 200.

As described, the user desires for a technology that can visualize effective measures (measures for improvement) to be taken in the entire user environment for achieving cost reduction. However, with the related art example, it is difficult to provide a management function that sufficiently fulfills the desire.

Accordingly, the management apparatus 100 according to an embodiment of the present invention provides the below-described scheme/mechanism that calculates the power consumption amount (current status value) of the currently used electronic device during a predetermined period and the estimated power consumption amount in a case where the substitute device is used within the predetermined period (estimate value) and processes/generates data that allows visual comparison between the calculated current status value and the estimate value.

Accordingly, the management apparatus 100 can provide an environment that visualizes an optimum proposal for achieving cost reduction in view of the use of the electronic device 200 in the user environment. Thereby, from the standpoint of cost reduction, the user can specifically identify an element/device in the system 1000 that is to be improved, and appropriately and effectively handle the element/device to be improved.

Next, functions and operations according to an embodiment of the present invention are described.

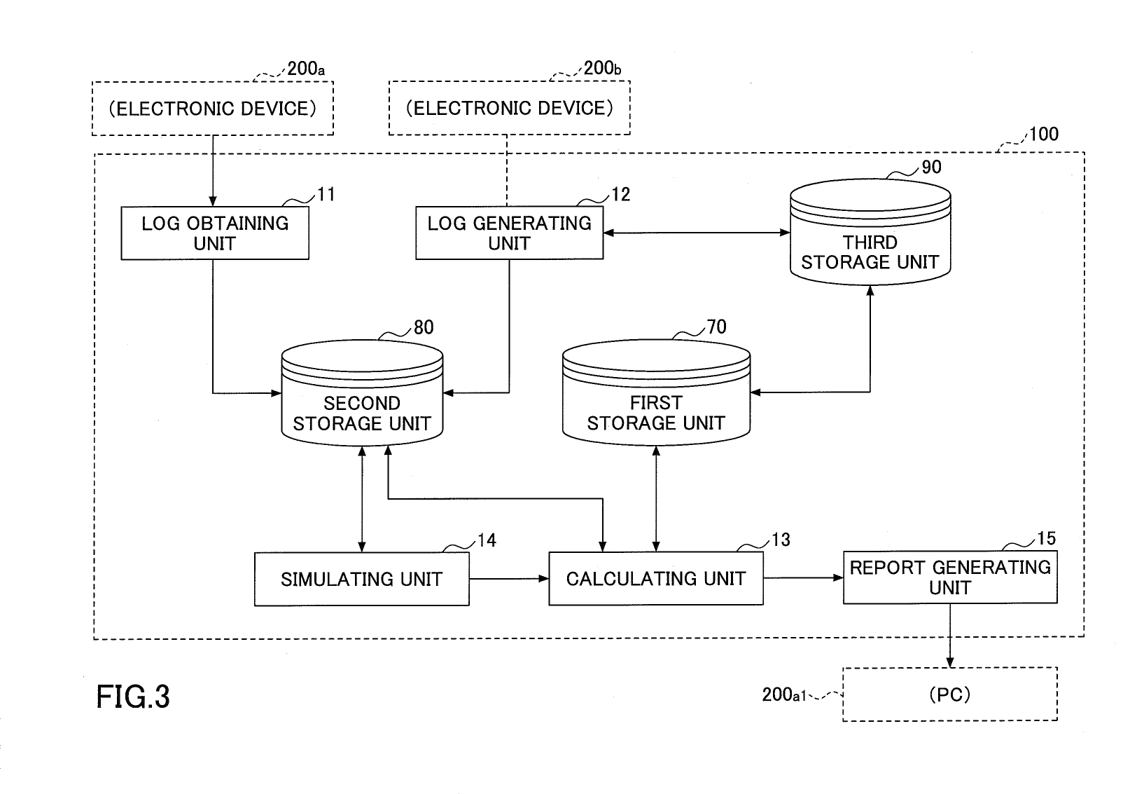

FIG. 3 is a schematic diagram illustrating a configuration of a management function of the management apparatus 100 according to an embodiment of the present invention. As illustrated in FIG. 3, the configuration of the management function includes, for example, a log obtaining unit 11, a log generating unit 12, a calculating unit 13, a simulating (estimating) unit 14, a report generating unit 15. The units 11-15 (and the below-described units 70-90) are function parts of the management apparatus 100. Accordingly, each of the functions of the management apparatus 100 including the management function is performed by cooperative operation of the function parts 11-15, 70-90 of the management apparatus 100.

The log obtaining unit 11 obtains a status/operation log from the electronic device 200a. As described above, the electronic device 200a is capable of notifying (transmitting) a status/operation log (history data) pertaining to the electronic device 200a by the electronic device 200a itself. That is, the electronic device 200a is capable of independently notifying (transmitting) a status/operation log (history data) pertaining to itself. Accordingly, the log obtaining unit 11 obtains the status/operation log by receiving log data transmitted from the electronic device 200a.

The electronic device 200a may transmit log data at the following timing. For example, in a case where the electronic device 200a detects an event occurring at a timing where an operation is executed in accordance with processing of a job or at a timing where the status (mode) of the electronic device 200a shifts to another mode, the electronic device 200a transmits log data to the log obtaining unit 11. The electronic device 200 may transmit the following log data. For another example, in a case of transmitting log data at a timing where execution of an operation occurs, the log data includes a time/date of the operation, a device type of the electronic device 200a, an identifier of the electronic device 200a, and a content of the operation (operation content or job content). For another example, in a case of transmitting log data at a timing where a change of status occurs, the log data includes a time/date of the status change, a device type of the electronic device 200a, an identifier of the electronic device 200a, and a content of the status (status content).

The log generating unit 12 generates a status/operation log of the electronic device 200b. As described above, the electronic device 200b is unable to notify (transmit) a status/operation log (history data) pertaining to the electronic device 200b by the electronic device 200b itself. Accordingly, the log generating unit 12 monitors the electronic device 200b. In a case where a change of status/operation is detected according to the results of the monitoring (monitoring results), the log generating unit 12 generates log data corresponding to the detected status/operation.

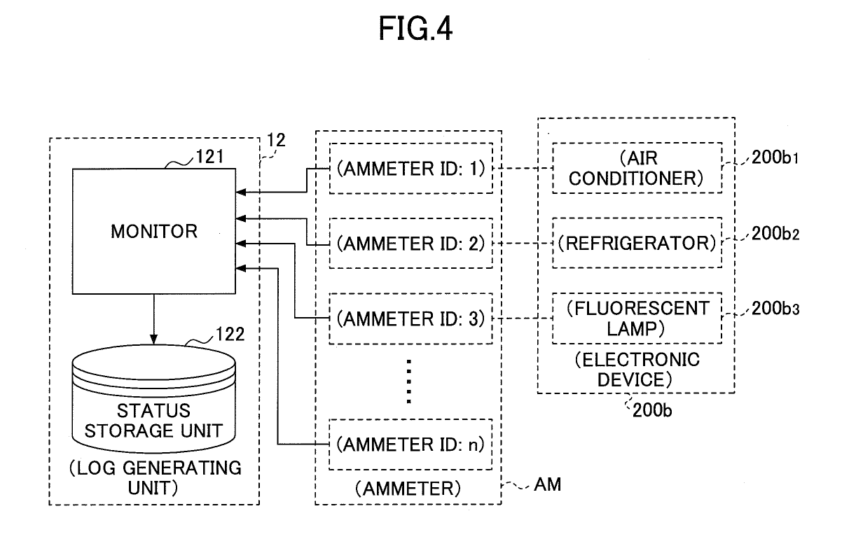

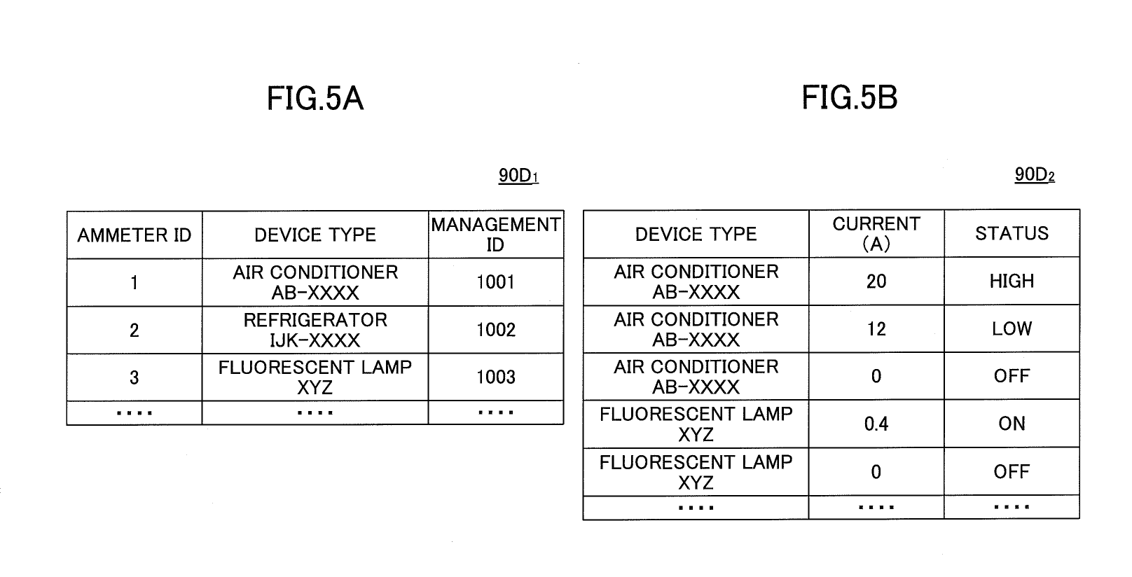

The above-described log generating operation of the log generating unit 12 is performed with the elements/parts illustrated in FIG. 4 and data illustrated in FIG. 5.

FIG. 4 is a schematic diagram illustrating an example of a configuration of the log generating unit 12 according to an embodiment of the present invention. As illustrated in FIG. 4, the log generating unit 12 includes a monitor 121 and a status storage unit 122. The monitor 12 has a function of monitoring the status/operation of the electronic device 200b. For example, the monitor 12 monitors changes of electric current (increase/decrease of electric current value) by obtaining the current value (measured value) from an ammeter AM placed in correspondence with each electronic device 200b. The status storage unit 122 includes a storage area for storing status data of each electronic device 200b (data pertaining to the status of each electronic device 200b) according to the monitoring results. In this embodiment, the “storage area” is a work memory assigned to the RAM 104 when the log generating unit 12 is activated. Therefore, the status data of the electronic device 200b is temporarily stored in the status storage unit 122.

FIG. 5 is a schematic diagram illustrating a configuration of device management data 90D according to an embodiment of the present invention. The device management data 90D of FIG. 5 is data used by the management apparatus 100 for managing the electronic device 200b. With reference to FIG. 3, the device management data 90D is stored in a third storage unit (also referred to as “device management data storage unit”) 90. The third storage unit 90 includes a predetermined storage area of a storage device of the management device 100.

The device management data 90D includes current ammeter management data 90D1 and status management data 90D2. The current ammeter management data 90D1 is data used for managing a corresponding relationship between the ammeter AM and the electronic device 200b. The status data management data 90D2 is data used for managing a corresponding relationship between the current value of each electronic device 200b and the status of each electronic device 200b.

The ammeter management data 90D1 includes one or more data sets having corresponding items including a ammeter identifier (ID), a device type, and a management identifier (ID). The data sets are managed in correspondence with each ammeter AM.

The item “ammeter ID” is for storing identification data of the ammeter (ammeter identification data). The item value of “ammeter ID” includes, for example, an identifier uniquely assigned to each ammeter AM. The item “device type” is for storing device type data of the electronic device 200b. The item value of “device type” includes, for example, the name of the device type (device type value) of the electronic device 200b. The item “management ID” is for storing identification data for allowing the management apparatus 100 to manage the electronic device 200b (management identification data). The item value of “management ID” includes, for example, an identifier (device ID) uniquely assigned to each electronic device 200b.

A user or an administrator may set the item values of the ammeter management data 90D1 in accordance with the connection status between the ammeter AM and the electronic device 200b by way of, for example, a predetermined interface (GUI, Graphical User Interface) of the management apparatus 100.

The status management data 90D2 includes one or more data sets having corresponding items including a device type, a current, and a status. The data sets are managed in correspondence with each electronic device 200b.

The item “device type” is for storing device type data of the electronic device 200b. Therefore, the status management data 90D2 and the ammeter management device 90D1 can be associated with each other by the item value of “device type” (device type data). The item “current” is for storing electric current data of a particular status of the electronic device 200b. The item value of “current” includes, for example, an electric current value of a particular status of the electronic device 200b. The item “status” is for storing status data of the electronic device 200b. The item value of “status” includes, for example, a status value of the electronic device 200b.

A user or an administrator may set the item values of the status management data 90D2 in accordance with the specifications of the electronic device 200b by way of, for example, a predetermined interface (GUI, Graphical User Interface) of the management apparatus 100.

Returning to FIG. 4, the monitor 121 monitors changes of current of the electronic device 200b by obtaining the current value from each ammeter AM. When the monitor 121 detects a change of current, the monitor 121 refers to the ammeter management data 90D1 and identifies the corresponding relationship between the electronic device 200b and the ammeter AM by which the current change is detected. Thereby, the monitor 121 obtains the device type of a corresponding electronic device 200b. Then, the monitor 121 refers to the status management data 90D2 based on the obtained device type data and identifies a corresponding relationship between the electric current value and status of the corresponding electronic device 200b. Thereby, the monitor 121 obtains a status data corresponding to the electric current data having a value nearest to the electric current value detected by the ammeter AM (monitoring result). The monitor 121 determines whether the current status is a status prior to the change of the detected change of electric current by referring to the obtained status data (current status) and the status data (status prior to change of electric current) detected from the corresponding electronic device 200b in a previous monitoring process. In a case where the monitor 121 determines that the status of the electronic device 200b has changed, log data is generated. The generated log data includes, for example, the device type of the corresponding electronic device 200b, the identifier of the corresponding electronic device 200b, and the status content of the corresponding electronic device 200b.

For example, in a case where the monitor 121 detects change of the electric current of an air conditioner 200b1, the monitor 121 refers to the ammeter management data 90D1 and obtains device type data “air conditioner AB-XXXX” of the air conditioner 200b1. Then, the monitor 121 refers to the status management data 90D2 based on the obtained device type data “air conditioner AB-XXXX” and obtains a status data “low” corresponding to the electric current data “12” having a value nearest to the electric current value “10” detected by the ammeter AM (monitoring result). The monitor 121 determines whether the current status is a status prior to the change of the detected change of electric current by referring to the obtained status data (current status) “low” and the status data (status prior to change of electric current) “high” detected from the corresponding electronic device 200b in a previous monitoring process. In a case where the monitor 121 determines that the status of the electronic device 200b has changed from “high” to “low”, log data is generated. The generated log data includes, for example, the time/date of the change of status “YY-MM-DDthh:mm:ss”, the device type “air conditioner AB-XXXX” of the corresponding electronic device 200b, the identifier “1001” of the corresponding electronic device 200b, and the status content “low” of the corresponding electronic device 200b.

Accordingly, the log generating unit 12 uses the function of the monitor 121 to generate log data of the corresponding electronic device 200b from which status change is detected by referring to the device management data 90D.

Returning to FIG. 3, the management apparatus 100 stores log data obtained by the log obtaining unit 11 or log data generated by the log generating unit 12 in a second storage unit (also referred to as “history management data storage unit”) 80 and manages the status/operation log of the electronic device 200 to be managed (management target). The second storage unit 90 includes a predetermined storage area of a storage device of the management device 100.

Next, log management data (history management data) is described.

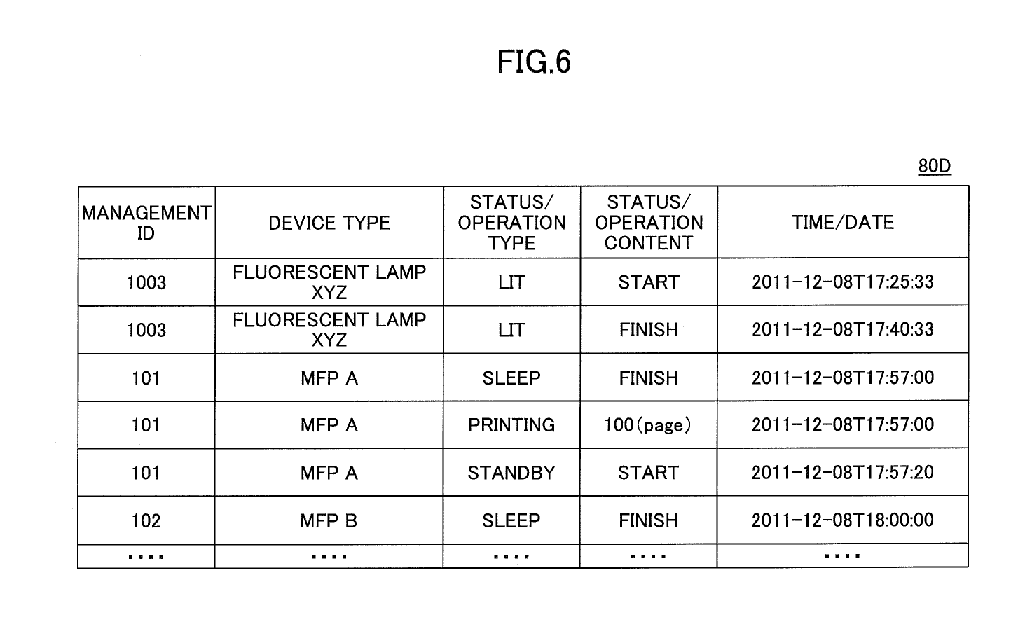

FIG. 6 is a schematic diagram illustrating a configuration of log management data 80D according to an embodiment of the present invention.

As illustrated in FIG. 6, the log management data 80D includes one or more data sets having corresponding items including a management ID, a device type, a status/operation type, a status/operation content, and a time/date. The data sets are managed in correspondence with log data obtained by the log obtaining unit 11 or log data generated by the log generating unit 12.

The item “management ID” is for storing management identification data of the electronic device 200. The item “device type” is for storing device type data of the electronic device 200. The item “status/operation type” is for storing type data of the status/operation of the electronic device 200 (status/operation type data). The item value of “status/operation type” includes, for example, a type name of a status/operation of the electronic device 200. The item “status/operation content” is for storing data of the content of a status/operation of the electronic device 200 (status/operation content data). The item value of “status/operation content” includes, for example, a status name/operation content value of the electronic device 200.

Next, specific examples (corresponding relationship) of the items values of “status/operation type” and “status/operation content” are described. As illustrated in FIG. 6, in a case where the electronic device is a fluorescent lamp 200b3, a value “start” or “finish” indicating the content of an illumination status is associated with a device status “lit”. Further, in a case where the electronic device 200 is a MFP 200a2, a value “start” or “finish” indicating the content of a sleep/standby status is associated with a device status “sleep/standby”. Further, in the case of the MFP 200a2, a value “100 (page)” indicating the number of pages of a printing job is associated with an operation “printing”.

The item “time/date” is for storing data of the time/date in which status of the electronic device 200 has changed or the time/date in which an operation by the electronic device 200 has occurred (status change/operation occurrence of the electronic device). The item value of “time/date” includes, for example, the time/date in which status of the electronic device 200 has changed or the time/date in which an operation by the electronic device 200 has occurred.

The log obtaining unit 11 or the log generating unit 12 accesses the second storage unit 80 and stores data items included in generated/obtained log data in correspondence with data items of the log management data 80D stored in the second storage unit 80. Thereby, a new data set corresponding to the log data is generated in the log management data 80D, and the status/operation log of the electronic device 200 is recorded in an order of, for example, the time (temporal order) in which the status has changed or the time (temporal order) in which the operation has been executed.

Returning to FIG. 3, the management apparatus 100 stores unit data pertaining to power consumption in a first storage unit (also referred to as “power consumption management data storage unit”) 70 for calculating the power consumption amount of the electronic device 200 to be managed. The first storage unit 70 includes a predetermined storage area of a storage device of the management device 100.

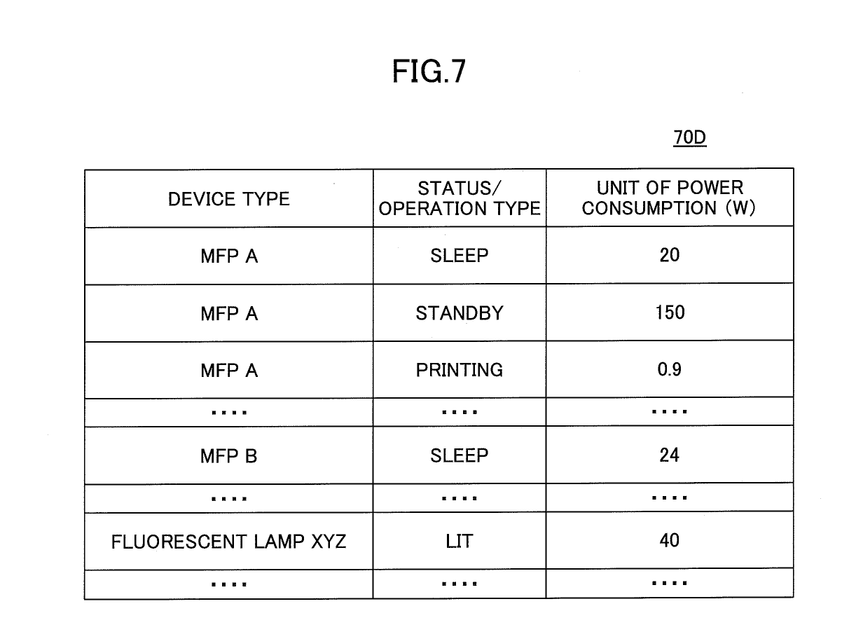

Next, power consumption management data is described with reference to FIG. 7.

FIG. 7 is a schematic diagram illustrating a configuration of power consumption management data 70D (example 1) according to an embodiment of the present invention.

As illustrated in FIG. 7, the power consumption management data 70D includes one or more data sets having corresponding items including a device type, a status/operation type, and unit of power consumption (power consumption unit). The data sets are managed in correspondence with a status or an operation estimated (anticipated) to occur in the electronic device 200.

The item “device type” is for storing device type data of the electronic device 200. The item “status/operation type” is for storing type data of the status/operation of the electronic device 200 (status/operation type data). The item “unit of power consumption” is for storing unit data of power consumption. The unit data of the power consumption is used for calculating the power consumption amount of the electronic device 200. The item value of “unit of power consumption” includes, for example, a reference value (unit data) for calculating the power consumption amount estimated to be consumed during a predetermined status or operation. The unit data used for calculating the power consumption amount of the electronic device 200 is also referred to as “power consumption unit data”.

Next, specific examples (corresponding relationship) of the items values of “status/operation type” and “unit of power consumption” are described. As illustrated in FIG. 7, in a case where the electronic device is a fluorescent lamp 200b3, a value “40 (W)” indicating the power consumption per time (in this example, per hour) of lighting the fluorescent lamp 200b3 is associated with a device status “lit”. Further, in a case where the electronic device 200 is a MFP 200a2, a value “20/150 (W)” indicating the power consumption per time (in this example, per hour) in a sleep/standby state is associated with a device status “sleep/standby”. Further, in the case of the MFP 200a2, a value “0.9 (W)” indicating the power consumption per page (per a predetermined printing job) of a printing operation is associated with an operation “printing”.

A user or an administrator may set the item values of the power consumption management data 70D in accordance with the specifications of the electronic device 200 by way of, for example, a predetermined interface (GUI, Graphical User Interface) of the management apparatus 100. Further, the electric current data of the status management data 90D2 may be calculated by using the power consumption unit data of the power consumption management data 70D. Accordingly, each of the items values of the status management data 90D2 may be dynamically set by the log generating unit 12 at a predetermined timing (e.g., at the time when the log generating unit 12 is activated) in accordance with the power consumption management data 70D.

Returning to FIG. 3, the calculating unit (operation unit) 13 calculates the amount of power consumption consumed by the use of the electronic device 200 during a predetermined period. The calculating unit 13 calculates the power consumption amount as follows.

First, the calculating unit 13 receives an input of a report period by way of a predetermined interface. The report period indicates a period in which power consumption amount is to be calculated. The calculating unit 13 accesses the second storage unit 80, refers to “time/date” of the log management data 80D, and obtains log management data 80D corresponding to the report period. Further, the calculating unit 13 accesses the first storage unit 7, refers to “device type” and “status/operation type” of the power consumption management data 70D, and obtains power consumption unit data having a data set matching the “type data” and the “status/operation type” of the log management data 80D.

As a result, the calculating unit 13 performs the following calculation in a case where the “status/operation type” of the corresponding log management data 80D has a value indicating a “device status”. In a case where “status/operation type” of the electronic device 200 is indicated as “device status”, the calculating unit 13 calculates the amount of power consumed (power consumption amount) when the electronic device 200 is in a predetermined status during a report period as follows. In order to calculate the power consumption amount in the case where “status/operation type” of the electronic device 200 is indicated as “device status”, the calculating unit 13 refers to data indicating a period (length of time) in which the electronic apparatus 200 maintains a predetermined status during the report period (i.e., period in which “device status” is maintained during the report period such as a period from “start” to “finish” of a corresponding device status) and data indicating a power consumption unit corresponding to the “device status” (e.g., power consumption amount per predetermined time of a corresponding device status). Further, in a case where “status/operation type” of the electronic device 200 is indicated as “device operation”, the calculating unit 13 calculates the amount of power consumed (power consumption amount) when the electronic device 200 is performing a predetermined operation during a report period as follows. In order to calculate the power consumption amount in the case where “status/operation type” of the electronic device 200 is indicated as “device operation”, the calculating unit 13 refers to data indicating a job process (e.g., job of printing a predetermined number of pages) executed during the report period and data indicating power consumption unit data corresponding to the device operation (e.g., power consumption amount per execution of predetermined job).

Thereby, the calculating unit 13 compiles the power consumption amount corresponding to each device status/device operation recorded in a corresponding log during the report period.

Then, the calculating unit 13 generates intermediate data including calculated values indicating the amount of power consumed when the electronic device 200 is in a predetermined status or when the electronic device 200 performs a predetermined operation. The “intermediate data” is to be used when generating the below-described report. The calculating unit 13 generates the intermediate data based on the calculated values of power consumption amount corresponding to a device status/device operation with respect to corresponding log management data 80D (report target). More specifically, the calculating unit 13 generates a data set (including corresponding log management data 80D including management ID data, device type data, time/date data, status/operation type data, and calculated value of power consumption amount that are associated with each other) in correspondence with each device status/device operation. The intermediate data is generated as a result of compiling the amount of power consumed when the electronic device 200 is in a predetermined status or when the electronic device 200 performs a predetermined operation during a report period.

The simulation (estimation) unit 14 simulates (estimates) a case where a substitute electronic device (e.g., first or second substitute device) 200, which is capable of achieving a predetermined device status recorded in a log (history content of history data) of a target electronic device (e.g., first or second target device) 200, substitutes the target electronic device 200 and achieves the predetermined device status. Further, a simulating unit (estimating unit) 14 simulates (estimates) a case where a substitute electronic device (e.g., first or second substitute device) 200, which is capable of performing a predetermined device operation recorded in a log (history content of history data) of a target electronic device (e.g., first or second target device) 200, substitutes the target electronic device 200 and performs the predetermined device operation. Then, simulating unit 14 estimates the power consumption amount in a case where the substitute electronic device 200 is used instead of (i.e., substitutes) the target electronic device 200.

The simulating unit 14 accepts input of substitute data by way of a predetermined interface. The substitute data includes data indicating, for example, device type change, status/operation change. The simulating unit 14 accesses the second storage unit 80, refers to “time/date” of the log management data 80D, and obtains log management data 80D corresponding to a report period. The simulating unit 14 changes the value of a corresponding data item of the obtained log management data 80D (replaces a target item value of log management data 80D with a value indicated in the substitute data) based on the substitute data and generates a log management data 80D to be used for simulation (hereinafter also referred to as “simulation log management data 80D). For example, in a case where the simulating unit receives input indicating “device type change (MFP A to MFP C), the simulating unit 14 changes the value of “device type” of the obtained log management data 80D from “MFP A” to “MFP C”.

Then, the simulating unit 14 sends the generated simulation log management data 80D to the calculating unit 13 and instructs the calculating unit 13 to calculate an estimated power consumption amount for the case where the target electronic device 200 is substituted with the substitute electronic device 200. In response to the instruction, the calculating unit 13 calculates the estimated power consumption amount (amount of power estimated to be consumed when the substitute electronic device 200 is in a predetermined status or when the substitute electronic device 200 performs a predetermined operation during a report period) and generates the intermediate data to be used for simulation. In other words, the calculating unit 13 not only generates intermediate data corresponding to a case where the electronic device 200 is currently being used but also generates intermediate data corresponding to a case where the substitute electronic device 200 is used.

The report generating unit 15 generates a report that enables visual comparison between a current status value (power consumption amount of a currently used electronic device (target electronic device) during a predetermined period) and an estimate value (estimated power consumption amount in a case where a substitute electronic device is used during the predetermined period). The report generating unit 15 generates (outputs) the report based on the intermediate data generated by the calculating part 13 as described below.

The report generating unit 15 sorts the intermediate data into groups of various device types based on “device type” of the intermediate data, and adds the values of the calculated power consumption amount in group units. As a result, the report generating unit 15 generates a visible report file by rendering based on the added values (total) of the power consumption amount of the intermediate data. That is, the report generating unit 15 processes the added values into predetermined visual data. For example, the report generating unit 15 generates a data file of a table or a graph based on the “management ID”, “device type”, and “total of power consumption amount” of the intermediate data. The sorting of the intermediate data is not limited to sorting into groups of device types. For example, the report generating unit 15 may sort the intermediate data into groups of time periods (predetermined periods) based on “time/date” of the intermediate data.

With the above-described method, the report generating unit 15 generates a report file corresponding to the use of the currently used electronic device (i.e. target electronic device) 200 based on the intermediate data corresponding to the use of the target electronic device 200. Further, based on the intermediate data corresponding to the use of the target electronic device 200 and the intermediate data corresponding to the use of the substitute electronic device 200 (i.e., simulation intermediate data), the report generating unit 15 performs a process of generating a report file that allows visual comparison between the power consumption amount at the time of using the target electronic device 200 and the power consumption amount at the time of using the substitute electronic device 200 in the entire user environment.

In other words, the report generating unit 15 processes/generates data that allows visual comparison between the power consumption amount before substituting the target electronic device 200 with the substitute electronic device 200 and the power consumption amount after substituting the target electronic device 200 with the substitute electronic device 200.

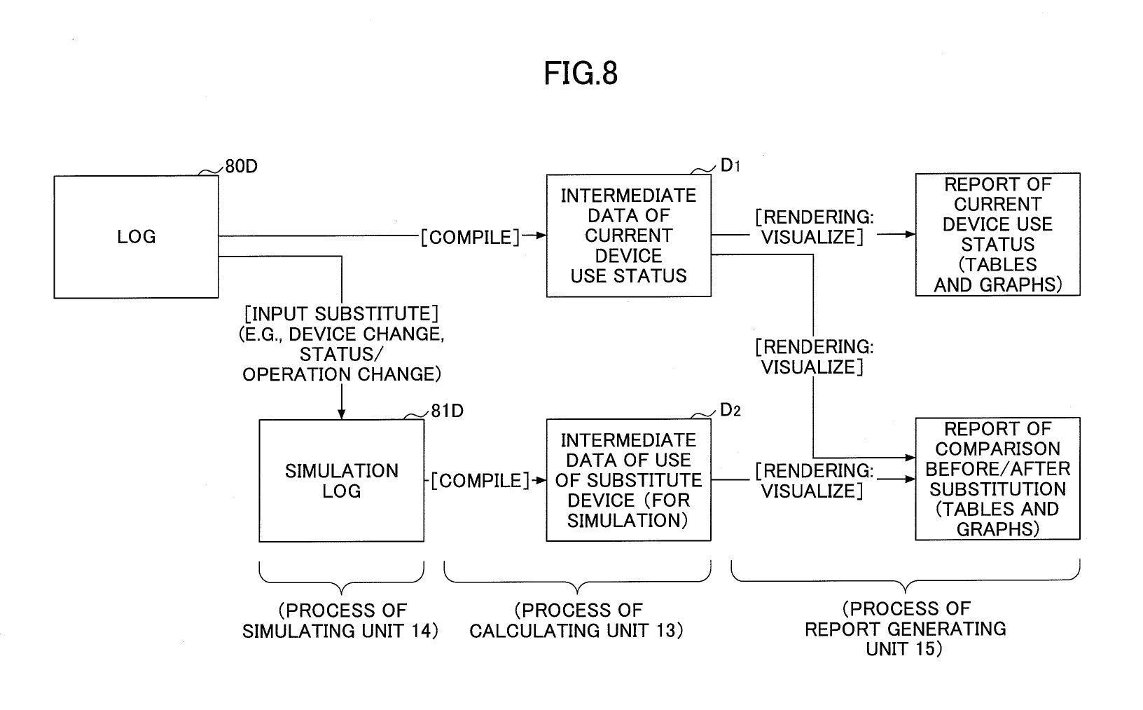

Next, a cooperative operation between the calculating unit 13, the simulating unit 14, and the report generating unit 15 is described with reference to FIG. 8. FIG. 8 is a schematic diagram illustrating an operation of generating a report according to an embodiment of the present invention.

With reference to FIG. 8, the calculating unit 13 of the management apparatus 100 compiles the power consumption amount corresponding to each data item “device status/device operation” recorded in a log during a report period, and generates intermediate data D1 corresponding to the use of the target electronic device (currently used electronic device) 200. Then, the report generating unit 15 of the management apparatus 100 generates a report corresponding to the use of the target electronic device based on the intermediate data D1 generated by the calculating unit 13. Further, the simulating unit 14 of the management apparatus 100 changes the log management data 80D to substitute data, and generates the simulation log management data 81D. Then, the calculating unit 13 of the management apparatus 100 compiles the estimated power consumption amount corresponding to each data item “device status/device operation” during a report period after the target electronic device 200 is substituted with the substitute electronic device 200 based on the simulation log management data 80D generated by the simulating unit 14. Then, the calculating unit 13 generates intermediate data (simulation intermediate data) D2 corresponding to the use of the substitute electronic device 200. Thereby, the report generating unit 15 of the management apparatus 100 generates a report that allows visual comparison between the power consumption amount before the substitution and the power consumption amount after the substitution in the entire user environment based on the intermediate data D1, D2 generated by the calculating unit 13.

Hence, the management function of the management apparatus 100 is achieved mainly by the cooperative operation of the above-described function parts 11-15, 70-90. The function of each of the above-described function parts 11-15, 70-90 is performed by loading a program (to be installed in the management apparatus 100) from a storage device (e.g., HDD, ROM) to a memory (e.g., RAM) and executing the program with an operation device (e.g., CPU). The program to be installed in the management apparatus 100 is software for executing the management function.

Next, procedures (steps) of an operation (cooperative operation among the function parts 11-15, 70-90) for executing the management function of the management apparatus 100 are described with the following flowcharts.

### <<Log Obtaining/Generating Process>>

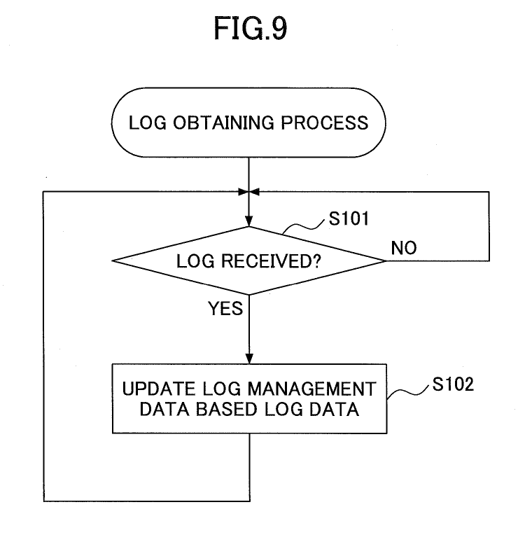

FIG. 9 is a flowchart illustrating procedures of a log obtaining process according to an embodiment of the present invention. The log obtaining process of FIG. 9 is performed by the log obtaining unit 11 of the management apparatus 100.

The log obtaining unit 11 determines whether log data of a status/operation log is received from an electronic device 200a (Step S101).

In a case where the log obtaining unit 11 receives log data (Yes in Step S101), the log obtaining unit 11 updates the log management data 80D based on the received log data (Step S102). In step S102, the log obtaining unit 11 accesses the second storage unit 80 and stores each item value included in the received log data to a corresponding data item of the log management data 80D of the second storage unit 80.

Thereby, the log obtaining unit 11 newly generates log management data 80D corresponding to the received log data and records the status/operation log of the electronic device 200a.

After the log obtaining unit 11 updates the log management data 80D, the log obtaining unit 11 shifts to a standby state and waits to receive further log data (No in Step S101).

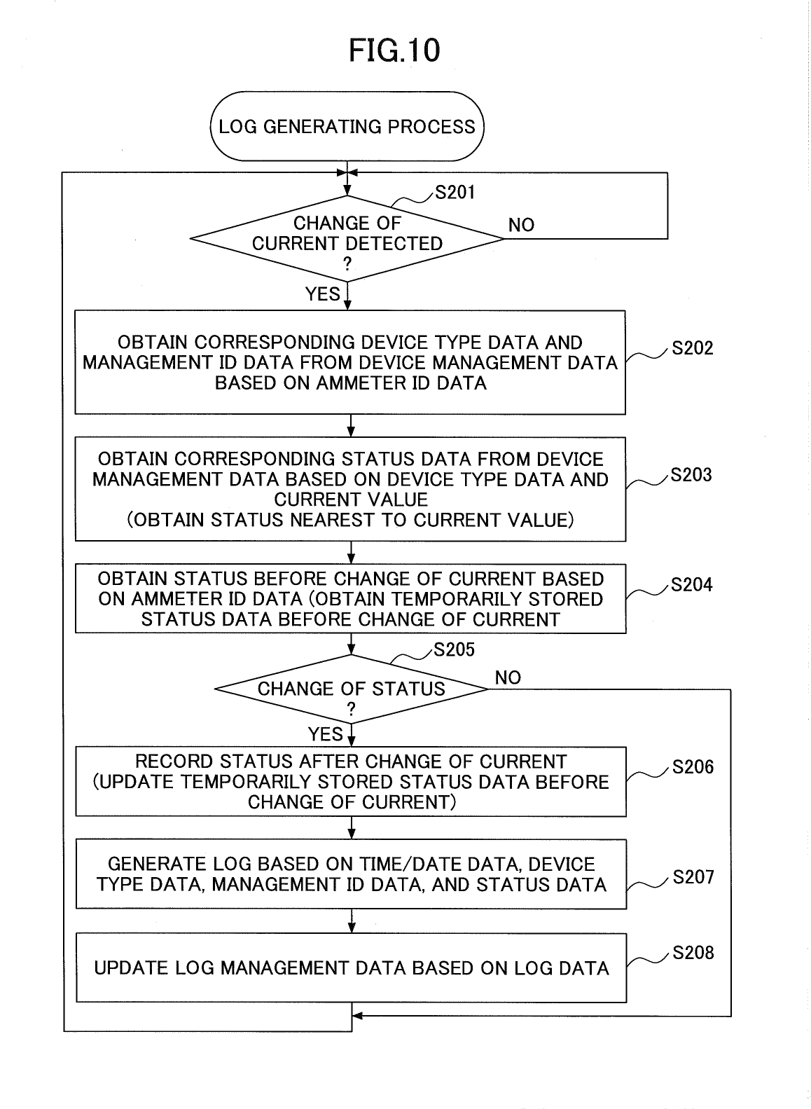

FIG. 10 is a flowchart illustrating procedures of a log generating process according to an embodiment of the present invention. The log generating process of FIG. 10 is performed by the log generating unit 12 of the management apparatus 100.

The log generating unit 12 monitors the electronic device 200b and determines whether change of electric current has been detected from the electronic device 200b (Step S201). In Step S201, the log generating unit 12 obtains an electric current value (measured value) from an ammeter AM arranged in correspondence with each electronic device 200b and detects change of electric current (increase/decrease of electric current value) of each electronic device 200b.

In a case where the log generating unit 12 detects change of electric current (Yes in Step S201) of the electronic device (hereinafter referred to as “change detected electronic device”) 200, the log generating unit 12 obtains device type data of the change detected electronic device 200 and management ID data assigned to the change detected electronic device 200 (Step S202). In Step S202, the log generating unit 12 accesses the third storage unit 90, and refers to the device management data 90D in the third storage unit 90 based on the ammeter ID data of the ammeter AM that has detected the change of electric current. The log generating unit 12 obtains device type data and management ID data associated with a matching ammeter ID data from the ammeter management data 90D1 of the device management data 90D.

Then, the log generating unit 12 obtains status data of the change detected electronic device 200b from the device management data 90D (Step S203). In Step S203, the log generating unit 12 refers to the device management data 90D based on the obtained device type data and the detected electric current value. The log generating unit 12 obtains electric current data associated with a matching device data from the status management data 90D2 of the device management data 90D. The log generating unit 12 identifies an electric current data having a value nearest to the electric current value detected by the ammeter AM among the obtained electric current data, and obtains status data corresponding to the identified electric current data.

Then, the log generating unit 12 obtains the status data of the change detected electronic device 200b prior to the change of electric current (Step S204). In Step S204, the log generating unit 12 accesses the status storage unit 122 that stores ammeter ID data and status data in correspondence with each electronic device 200b according to a previous monitoring process (previous monitoring result). Further, the log generating unit 12 obtains status data associated with matching ammeter ID data based on the ammeter ID data of the ammeter AM that has detected the change of electric current.

Then, the log generating unit 12 determines whether the current status is a status that has changed from the status prior to the change of electric current by referring to the status data (current status) obtained in Step S203 and the status data (status prior to change of electric current) obtained in Step S204 (Step S205). In Step S205, the log generating unit 12 compares the values of the obtained status data and determines whether status has changed based on the comparison result.

In a case where the log generating unit 12 determines that the current status is different from the status prior to the change of electric current (change of status) by confirming change of the values of the obtained status data (Yes in Step S205), the log generating unit 12 records the current status (i.e. result of current monitoring process) (Step S206). In Step S206, the log generating unit 12 accesses the status storage unit 122 and updates the status data associated with the matching ammeter ID data based on the ammeter ID data of the ammeter AM that has detected the change of electric current. The status data is updated with the status data obtained in Step S203 (i.e. current status data).

Then, the log generating unit 12 generates log data based on time/date data, device type data, management ID data, and status data (Step S207). In Step S207, the log generating unit 12 obtains the time/date in which change of device status was confirmed from a clock circuit (not illustrated) of the management apparatus 100 and assumes the obtained time/date as time/date data. The device type data and the management ID data are the data obtained in Step S202. The status data is the data obtained in Step S203. Accordingly, the log generating unit 12 generates log data including, for example, status change time/date data, device type of the electronic device 200b, management ID assigned to the electronic device 200b, status content obtained from the electric current change of the electronic device 200b.

Then, the log generating unit 12 updates the log management data 80D based on the generated log data (Step S208). In Step S208, the log generating unit 12 accesses the second storage unit 80 and stores each item value included in the generated log data to a corresponding data item of the log management data 80D of the second storage unit 80.

Thereby, the log generating unit 12 newly generates log management data 80D corresponding to the generated log data and records the status/operation log of the electronic device 200b.

After the log generating unit 12 updates the log management data 80D, the log generating unit 12 shifts to a standby state and waits for detection of current change of the electronic device 200b (No in Step S201). In a case where the log generating unit 12 determines that the current status has not changed from the status prior to the electric current change (No in Step S205), the log generating unit 12 skips the processes of Steps S206-S208 and shifts to the process of Step S201 (process of detecting current change).

Accordingly, the management apparatus 100 records/stores the log data obtained by the log obtaining unit 11 and/or the log data generated by the log generating unit 12 and manages the status/operation log of the electronic device (management target) 200.

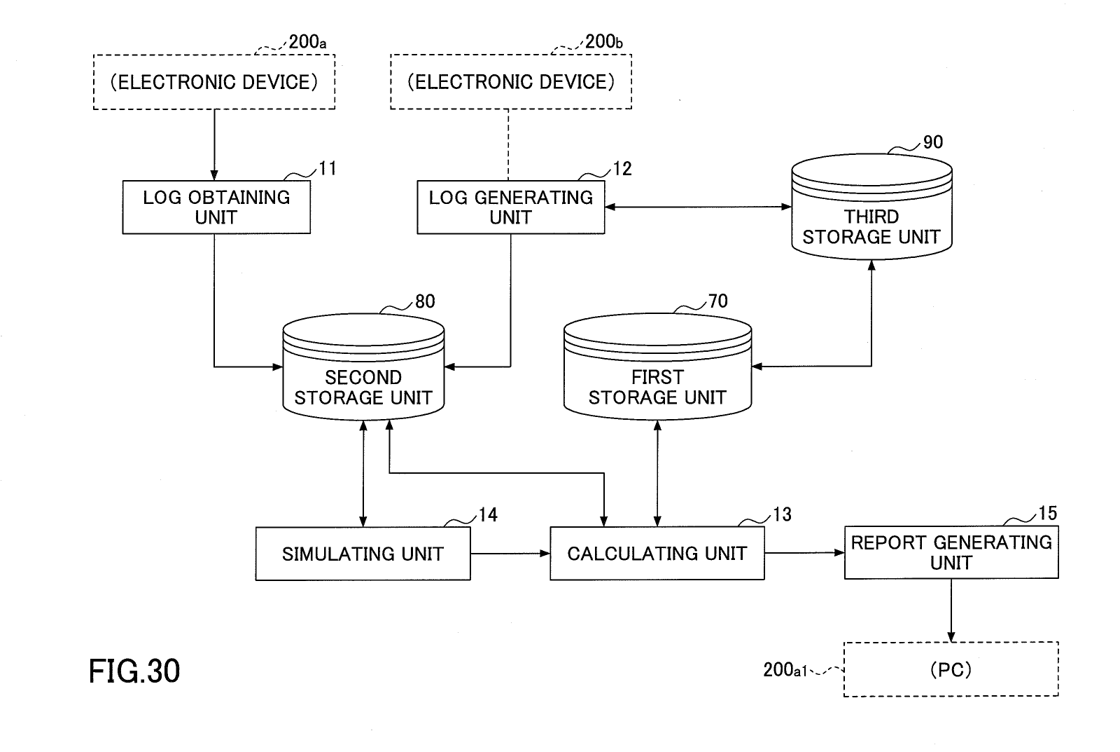

Although the management apparatus 100 of this embodiment executes the management function by a configuration including the above-described function parts 11-15, 70-90 as illustrated in FIG. 3, the management apparatus 100 is not limited to such configuration. For example, as illustrated in the below-described FIG. 30, the arrangement of the function parts 11-15, 70-90 for executing the management function may be altered as long as the function parts 11-15, 70-90 can cooperatively operate with each other for executing the management function. For example, each of the function parts 11-15, 70-90 may be included in separate data processing apparatuses (e.g., computers) and communicably connected to each other by a network.

Alternatively, plural functions parts may be extracted from the function parts 11-15, 70-90, so that the extracted function parts are provided in a single data processing apparatus. In other words, the function parts 11-15, 70-90 may be arbitrarily combined with each other according to the user environment. Thereby, the usability of the management function can be improved.

Further, one or more of the function parts 11-15, 70-90 may be provided in a hardware configuration as illustrated in FIG. 2. For example, in a case of executing the function of the log obtaining unit 11 with the a data processing apparatus (e.g., management apparatus 100) having a configuration illustrated in FIG. 2, a process corresponding to the function is performed by loading a program installed in the data processing apparatus from the ROM 105 to the RAM 104 and executing the program with the CPU 105. For example, in a case of executing the function of the second storage unit 80 with a data processing apparatus having a configuration illustrated in FIG. 2, a storage device (e.g., HDD 108) of the data processing apparatus may be used as the second storage unit 80. In other words, the CPU 106 of the data processing apparatus serving as the log obtaining unit 11 reads/writes data with respect to a storage device (e.g., HDD 108) serving as the second storage unit 80 by way of a network, an OS, or the like.

### <<Basic Process of Generating a Report>>

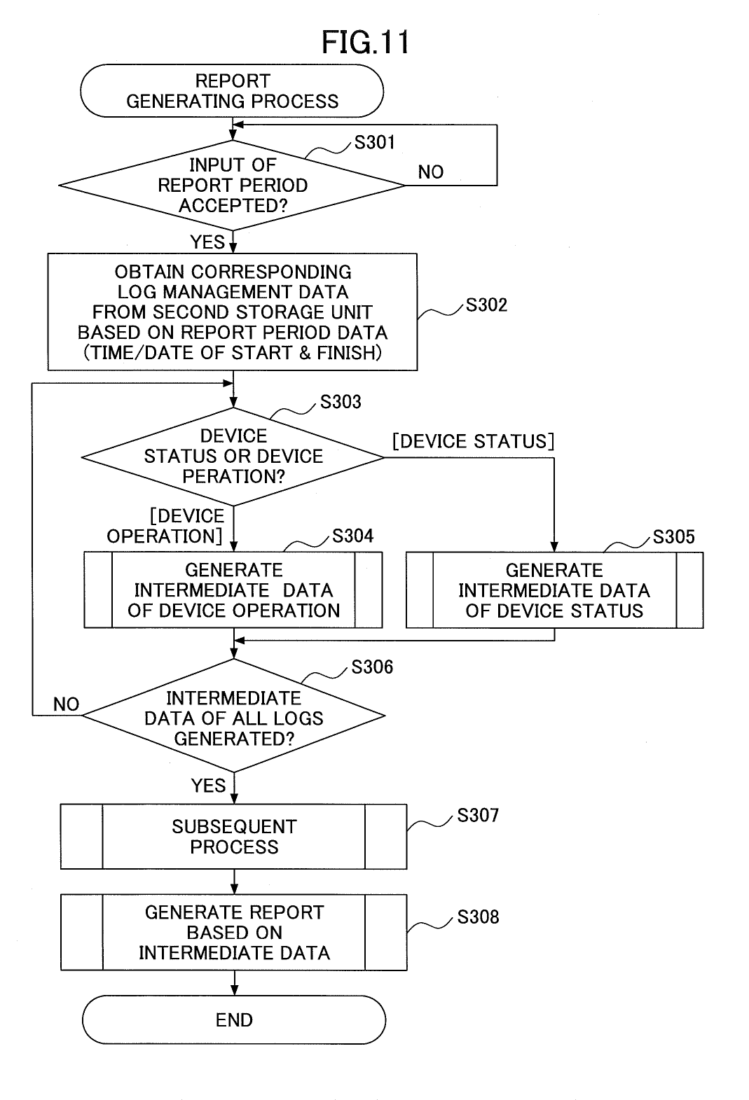

FIG. 11 is a flowchart illustrating procedures of a report generating process according to an embodiment of the present invention. The report generating process of FIG. 11 is performed by the calculating unit 13 and the report generating unit 15.

The calculating unit 13 accepts input of a report period (period for calculating power consumption amount) by way of a predetermined interface (Yes in Step S301).

The calculating unit 13 obtains log management data 80D corresponding to the report period (Step S302). In Step S302, the calculating unit 13 accesses the second storage unit 80D and refers to “time date” of the log management data 80D. The calculating unit 13 obtains log management data 80D having a “time/date” value within the report period based on the time/date of the start and finish of the report period.

Then, the calculating unit 13 determines whether the “status/operation type” of the obtained log management data 80D is a value indicating “device operation” or “device status” (Step S303).

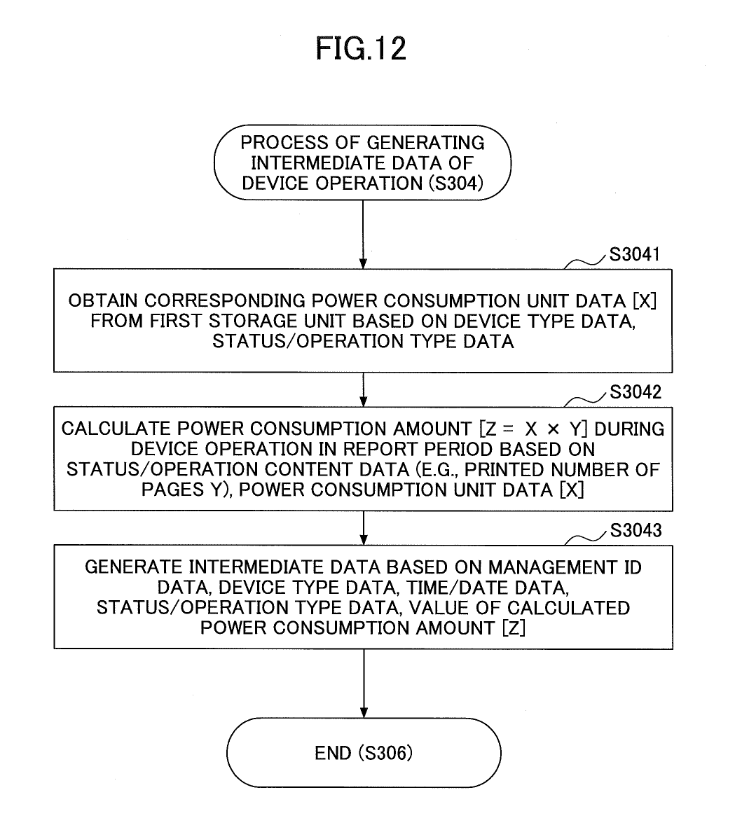

In a case where the calculating unit 13 determines that the “status/operation type” of the obtained log management data 80D is a value indicating “device operation” (“Device operation” in Step S303), the calculating unit 13 generates intermediate data D1 of a device operation that falls within the report period (Step S304). The intermediate data D1 of the device operation is intermediate data corresponding to the use of the target electronic device (i.e., electronic device that is currently used). The process of generating the intermediate data D1 of the device operation is described in detail below with reference to FIG. 12.

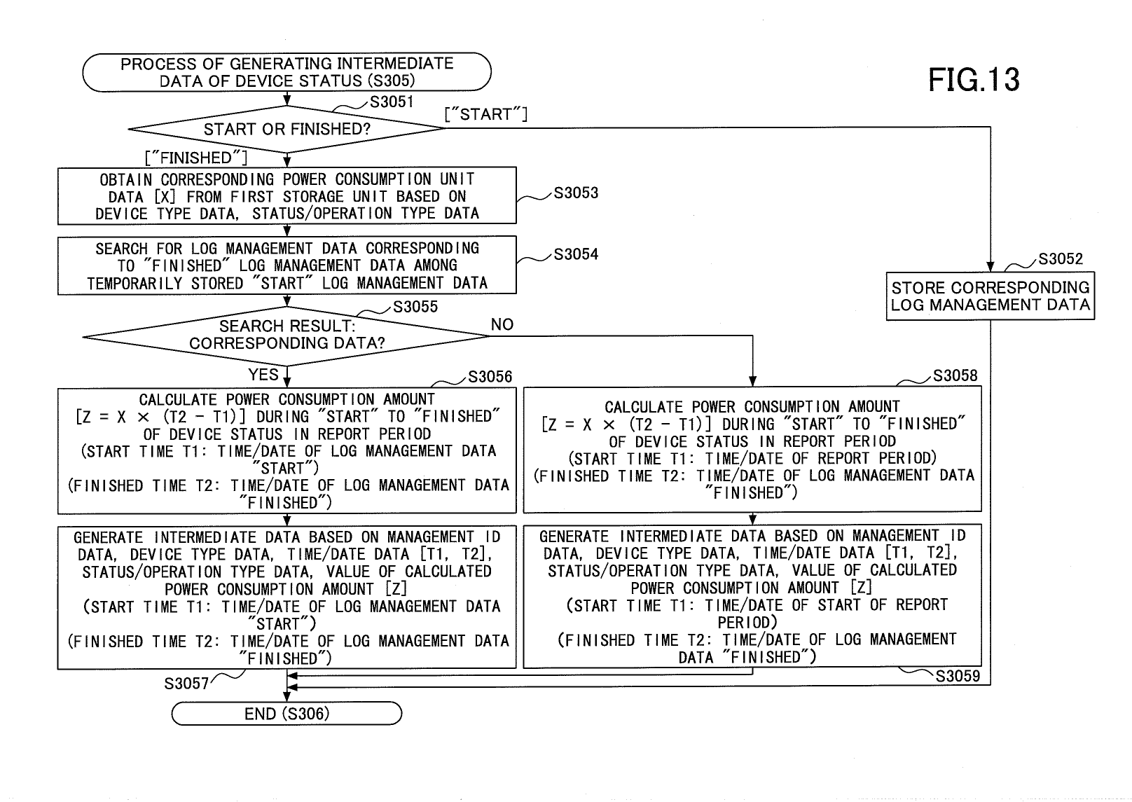

In a case where the calculating unit 13 determines that the “status/operation type” of the obtained log management data 80D is a value indicating “device status” (“Device status” in Step S303), the calculating unit 13 generates intermediate data D1 of a device status that falls within the report period (Step S305). The intermediate data D1 of the device status is also intermediate data corresponding to the use of the target electronic device (i.e., electronic device that is currently used). The process of generating the intermediate data D1 of the device status is described in detail below with reference to FIG. 13.

Then, the calculating unit 13 determines whether the process of Step S304 or Step S305 has been performed on all log management data 80D (i.e., all logs recorded during the report period) obtained in Step S302 (Step S306).

In a case where the calculating unit 13 determines that the process of Step S304 or Step S305 has not been performed on all log management data 80D (No in Step S306), the calculating unit 13 returns to the process of Step S303 (process of determining status/operation type). In other words, the calculating unit 13 repeats the processes in Steps S303-S306 until the process of Step S304 or Step S305 is performed on all log management data 80D obtained in Step S302.

In a case where the calculating unit 13 determines that the process of Step S304 or Step S305 has been performed on all log management data 80D (Yes in Step S306), the calculating unit 13 performs a subsequent process (Step S307). In this embodiment, the subsequent process is performed in view of the following situation.

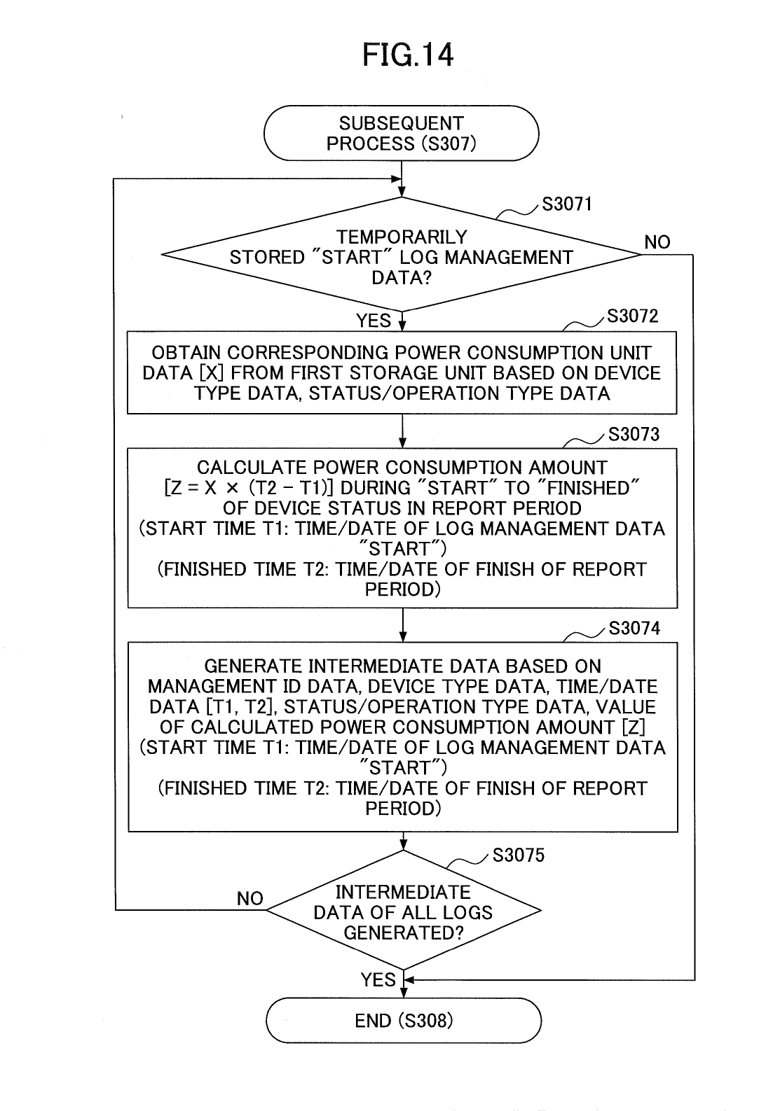

As described above, the report period is arbitrarily performed by, for example, a user of the management apparatus 100. Therefore, the obtained log management data 80D may not always include the time/date of the start or finish of a predetermined device status. Thus, the calculating unit may not be able to obtain a value indicating a period (length of time) in which the electronic device 200 maintains the predetermined device status during the report period. Accordingly, the calculating unit 13 may not be able to calculate the power consumption amount consumed when the electronic device 200 is in the predetermined device status during the report period. In this situation, the subsequent process is performed. For example, in a case where only the time/date of the start of a device status is obtained from the log management data 80D according to the input report period, the subsequent process is performed by assuming that the time/date of the finish indicated in the input report period corresponds to the time/date of the finish of the predetermined device status, calculating the power consumption amount based on the obtained time/date of the start of the device status and the assumed time/date of the finish of the device status, and generating the intermediate data D1 according to the calculated power consumption amount. Likewise, in a case where only the time/date of the finish of a device status is obtained from the log management data 80D according to the input report period, the subsequent process is performed by assuming that the time/date of the start indicated in the input report period corresponds to the time/date of the start of the predetermined device status, calculating the power consumption amount based on the obtained time/date of the finish of the device status and the assumed time/date of the start of the device status, and generating the intermediate data D1 according to the calculated power consumption amount. Thereby, even in a case where the period in which the electronic device 200 maintains the predetermined device status during the report period cannot be identified, the calculating unit 13 can generate the intermediate data D1 for the predetermined device status. The subsequent process of Step S307 is described in detail below with reference to FIG. 14.

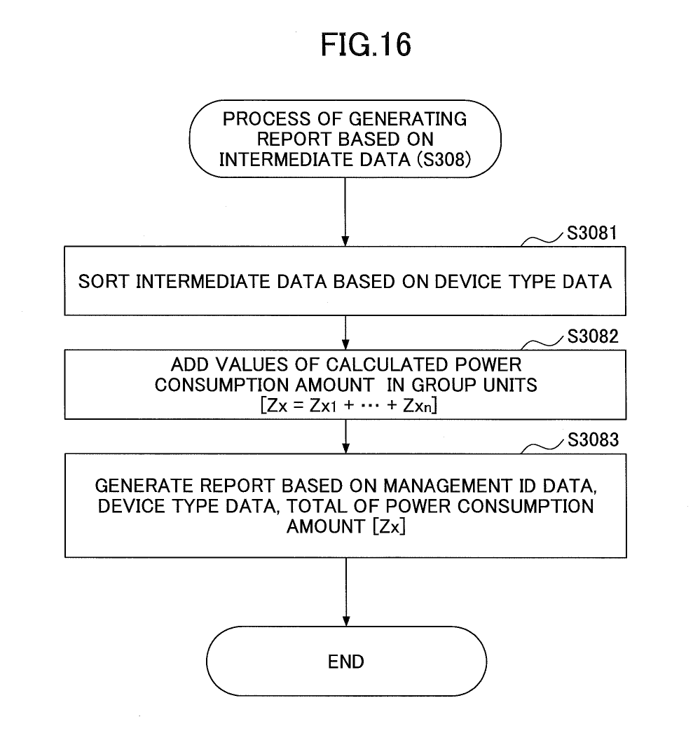

Then, the report generating unit 15 generates a report based on the intermediate data D1 generated by the calculating unit 13 (Step S308). In Step S308, the report generating unit 15 generates a report file that allows the power consumption amount of the use of the target electronic device 200 to be visually confirmed. The process of generating the report is described in detail below with reference to FIG. 16.

Hence, the management apparatus 100 can generate intermediate data D1 of the use of the target electronic device 200 by compiling the power consumption amount corresponding to each device status/device operation recorded as a log during the report period. Further, the management apparatus 100 can process/generate data that allows the power consumption amount of the use of the target electronic device 200 to be visually confirmed based on the generated intermediate data D1.

Next, the above-described processes performed in Steps S304, S305, S307 of FIG. 11 are described in detail with the following examples. In the following examples, the accepted input report period of Step S301 of FIG. 11 indicates a period of “2011-12-08717:00:00-18:00:00”.

### <<Generating Intermediate Data of Device Operation>>

FIG. 12 is a flowchart illustrating an example of the process of generating intermediate data of the device operation of Step S304.

The calculating unit 13 obtains a power consumption unit data [X] (power consumption amount per predetermined job process) corresponding to a device operation recorded as a log from the power consumption management data 70D (Step S3041). In Step S3041, the calculating unit 13 accesses the first storage unit 70 and refers to “device type” and “status/operation type” of the power consumption management data 70D. The calculating unit 13 obtains the power consumption unit data in a data set that matches the “device type” and “status/operation type” of the log management data 80D obtained in Step S302.

For example, the log management data 80D may have the data configuration illustrated in FIG. 6, the power consumption data 70D may have the data configuration illustrated in FIG. 7. Thus, “0.9 (W)” is obtained as a value of a power consumption unit data (value of power consumption per page during a printing operation) corresponding to a printing operation of device type “MFP A” recorded as an operation log (operation history).

Returning to FIG. 12, the calculating unit 13 calculates the power consumption amount when the electronic device 200 is performing a predetermined operation during a report period (Step S3042). In Step S3042, the calculating unit 13 calculates a power consumption amount when the electronic device 200 is performing a predetermined operation during a report period [Z=X×Y] based on “status/operation content” [Y] of the log management data 80D obtained in Step S302 and “power consumption unit” [X].

For example, in a case where the value of the “status/operation content” of the log management data 80D is “100 (page)”, the calculated power consumption amount when performing a printing operation is [90=0.9×100].

Accordingly, the calculating unit 13 generates the intermediate data D1 including the calculated value [Z] of the power consumption amount when the electronic device 200 is performing the predetermined operation during the report period (Step S3043). In Step S3043, the calculating unit 13 generates data sets (including “management ID”, “device type”, “time/date”, “status/operation type” of the log management data 80D obtained in Step S302 in association with calculated value [Z] of the power consumption amount) in correspondence with each device operation.

### <<Generating Intermediate Data of Device Status>>

FIG. 13 is a flowchart illustrating an example of the process of generating intermediate data of the device status of Step S305 of FIG. 11.

The calculating unit 13 determines whether the “status/operation content” of the log management data 80D indicates a value “start” or a value “finish” (Step S3051). That is, in Step S3051, the calculating unit 13 determines whether the “status/operation content” of the log management data 80D obtained in Step S302 indicates a value “start” or a value “finish”.

In a case where the calculating unit 13 determines that the “status/operation content” indicates “start” (Start in Step S3051), the calculating unit 13 temporarily stores the obtained log management data 80D (Step S3052) and proceeds to Step S306. In Step S306, a process of confirming execution of an intermediate data generating process is performed. In Step S3052, the calculating unit 13 stores the value “start” of the item “device status content” of the log management data 80D in a predetermined storage space (work memory) of a storage device of the management apparatus 100.

In a case where the calculating unit 13 determines that the “status/operation content” indicates “finish” (Finish in Step S3051), the calculating unit 13 obtains a power consumption unit data [X] (power consumption amount per predetermined time) corresponding to a device status recorded as a log from the power consumption management data 70D (Step S3053). In Step S3053, the calculating unit 13 accesses the first storage unit 70 and refers to “device type” and “status/operation type” of the power consumption management data 70D. The calculating unit 13 obtains the power consumption unit data in a data set that matches the “device type” and “status/operation type” of the log management data 80D obtained in Step S302.

For example, the log management data 80D may have the data configuration illustrated in FIG. 6, the power consumption data 70D may have the data configuration illustrated in FIG. 7. Thus, “40 (W)” is obtained as a value of a power consumption unit data (value of power consumption per hour when the fluorescent lamp XYZ is in a lit status) corresponding to an illumination status of device type “fluorescent lamp XYZ” recorded as a status log (status history).

Returning to FIG. 13, the calculating unit 13 searches for a log management data 80D having the same device status including a device status content corresponding to the device status content “finish” from the log management data 80D (which includes device status content “start”) temporarily stored in the predetermined storage space (work memory) (Step S3054). In Step S3054, the calculating unit refers to the items of the stored log management data 80D and searches for data having an item(s) corresponding to the log management data 80D determined to include an item “status/operation content” indicating a value “finish”.

Then, based on the result of the search, the calculating unit 13 determines whether a log management data 80D having the same device status including a device status content corresponding to the device status content “finish” is found (identified) in the log management data 80D (which includes device status content “start”) temporarily stored in the predetermined storage space (work memory) (Step S3055).

In a case where the calculating unit 13 determines that there exists a log management data 80D having the same device status including a device status content corresponding to the device status content “finish” (Yes in Step S3055), the calculating unit 13 calculates the power consumption amount from “start” to “finish” during the report period (Step S3056). In Step S3056, the calculating unit 13 assumes that the time/date corresponding to the device status content “start” of the log management data 80D (log management data found by the search) is the time/date of the start [T1] of a calculation period (period for calculating a period (length of time) in which the electronic device 200 maintains a predetermined device status during the report period). Further, the calculating unit 13 assumes that the time/date corresponding to the device status content “finish” of the log management data 80D (log management data found by the search) is the time/date of the finish [T2] of the calculation period. Then, the calculating unit 13 calculates the calculation period [T2−T1] (i.e., a period (length of time) in which the electronic device 200 maintains a predetermined device status during the report period) based on data indicating time/date T1 and T2. Then, the calculating unit 13 calculates a power consumption amount when the electronic device 200 is in a predetermined state during a report period [Z=X×(T2−T1)] based on the “power consumption unit” [X] obtained in Step S3053.

For example, with reference to FIG. 6, status log values “start” and “finish” are recorded as the status “lit” of device type “fluorescent lamp XYZ” in the log management data 80D. In this case, the following power consumption value can be calculated where the value of “time/date” corresponding to “finish” is “2011-12-08T17:40:33” and the value of “time/date” corresponding to “start” is “2011-12-08T17:25:33”. That is, in this case, the period (length of time) in which the electronic device 200 maintains the device status “lit” during the report period (i.e., calculation period) is 15 minutes. Because the value of “power consumption unit” corresponding to “lit” (in this example, 40 W) is the power consumption amount per hour, conversion of time units is to be performed (in this example, 0.25=( 15/60)). Accordingly, the calculated power consumption amount when the fluorescent lamp XYY is in the lit status is [10=40×0.25].

Returning to FIG. 13, the calculating unit 13 calculates the intermediate data D1 including the calculated value [Z] of the power consumption amount when the electronic device 200 is in a predetermined state from “start” to “finish” during the report period (Step S3057). In Step S3057, the calculating unit 13 generates the following data set in correspondence with each device status. The data set generated by the calculating unit 13 includes “log management ID (log management ID of the log management data 80D corresponding to device status content of “start” and “finish)” data, “device type” data, “time/date (including start time/date of device status: T1, finish time/date of device status: T2)” data, “status/operation type” data, and “calculated power consumption amount [Z]” data that are associated with each other.

On the hand, in a case where the calculating unit 13 determines that a log management data 80D having the same device status including a device status content corresponding to the device status content “finish” does not exist (No in Step S3055), the calculating unit 13 calculates the power consumption amount until the finish of the report period (Step S3058). In Step S3058, the calculating unit 13 assumes that the time/date of “start” indicated in the input report period is the time/date of the start [T1] of the calculation period. Further, the calculating unit 13 assumes that the time/date corresponding to the device status content “finish” of the log management data 80D (log management data determined to include an item “status/operation content” indicating a value “finish”) is the time/date of the finish [T2] of the calculation period. Then, the calculating unit 13 calculates the calculation period [T2−T1] (i.e., a period (length of time) in which the electronic device 200 maintains a predetermined device status during the report period) based on data indicating time/date T1 and T2. Then, the calculating unit 13 calculates a power consumption amount when the electronic device 200 is in a predetermined state during a report period [Z=X×(T2−T1)] based on the “power consumption unit” [X] obtained in Step S3053.

For example, with reference to FIG. 6, only status log value “finish” is recorded as the status “sleep” of device type “MFP A” in the log management data 80D. In this case, the following power consumption value can be calculated where the value of “time/date” corresponding to “finish” is “2011-12-08T17:57:00” and the value of “time/date” corresponding to “start” is “2011-12-08T17:00:00”. That is, in this case, the period (length of time) in which the electronic device 200 maintains the device status “sleep” during the report period (i.e., calculation period) is 57 minutes. Because the value of “power consumption unit” corresponding to “sleep” (in this example, 20 W) is the power consumption amount per hour, conversion of time units is to be performed (in this example, 0.95=( 57/60)). Accordingly, the calculated power consumption amount when the MFP A is in a sleep status is [19=20×0.95].

Returning to FIG. 13, the calculating unit 13 calculates the intermediate data D1 including the calculated value [Z] of the power consumption amount when the electronic device 200 is in a predetermined state until the finish of the report period (Step S3059). In Step S3059, the calculating unit 13 generates the following data set in correspondence with each device status. The data set generated by the calculating unit 13 includes “log management ID (log management ID of the log management data 80D corresponding to device status content of “finish)” data, “device type” data, “time/date (including start time/date of report period: T1, finish time/date of device status: T2)” data, “status/operation type” data, and “calculated power consumption amount [Z]” data that are associated with each other.

### <<Subsequent Process>>

FIG. 14 is a flowchart illustrating an example of the subsequent process of Step S307 of FIG. 11.

The calculating unit 13 determines whether log management data 80D including a device status content having a value “start” in a predetermined storage area (work memory) of the storage device of the management apparatus 100 (Step S3071).

In a case where the calculating unit 13 determines that a corresponding log management data 80D is stored (Yes in Step S3071), the calculating unit 13 obtains a power consumption unit data [X](power consumption amount per predetermined time) corresponding to a device status recorded as a log from the power consumption management data 70D (Step S3072). In Step S3072, the calculating unit 13 accesses the first storage unit 70 and refers to “device type” and “status/operation type” of the power consumption management data 70D. The calculating unit 13 obtains the power consumption unit data in a data set that matches the “device type” and “status/operation type” of the corresponding log management data 80D of Step S3071.

For example, the log management data 80D may have the data configuration illustrated in FIG. 6, the power consumption data 70D may have the data configuration illustrated in FIG. 7. Thus, “150 (W)” is obtained as a value of a power consumption unit data (value of power consumption per hour during a standby state) corresponding to a standby state of device type “MFP A” recorded as a status log (status history).

Returning to FIG. 14, the calculating unit 13 calculates the power consumption amount from “start” during the report period (Step S3073). In Step S3073, the calculating unit 13 assumes that the time/date corresponding to the device status content “start” of the log management data 80D (log management data including a device status content having a value “start”) is the time/date of the start [T1] of the calculation period. Further, the calculating unit 13 assumes that the time/date of the finish of the input report period is the time/date of the finish [T2] of the calculation period. Then, the calculating unit 13 calculates the calculation period [T2−T1] (i.e., a period (length of time) in which the electronic device 200 maintains a predetermined device status during the report period) based on data indicating time/date T1 and T2. Then, the calculating unit 13 calculates a power consumption amount when the electronic device 200 is in a predetermined state during a report period [Z=X×(T2−T1)] based on the “power consumption unit” [X] obtained in Step S3072.

For example, with reference to FIG. 6, status log value “start” is recorded as the status “standby” of device type “MFP A” in the log management data 80D. In this case, the following power consumption value can be calculated where the value of “time/date” corresponding to “finish” is “2011-12-08T18:00:00” and the value of “time/date” corresponding to “start” is “2011-12-08T17:57:20”. That is, in this case, the period (length of time) in which the electronic device 200 maintains the device status “standby” during the report period (i.e., calculation period) is 3 minutes. Because the value of “power consumption unit” corresponding to “standby” (in this example, 150 W) is the power consumption amount per hour, conversion of time units is to be performed (in this example, 0.05=( 3/60)). Accordingly, the calculated power consumption amount when the MFP A is in the standby status is [7.5=150×0.05].

Returning to FIG. 14, the calculating unit 13 calculates the intermediate data D1 including the calculated value [Z] of the power consumption amount when the electronic device 200 is in a predetermined state from “start” during the report period (Step S3074). In Step S3074, the calculating unit 13 generates the following data set in correspondence with each device status. The data set generated by the calculating unit 13 includes “log management ID (log management ID of the log management data 80D corresponding to device status content of “start”)” data, “device type” data, “time/date (including start time/date of device status: T1, finish time/date of report period: T2)” data, “status/operation type” data, and “calculated power consumption amount [Z]” data that are associated with each other.

Then, the calculating unit 13 determines whether the processes of Steps S3072-S3074 (intermediate data generating operation) has been performed on all log management data 80D (all log management data including a device status content having a value “start”) identified in Step S3071 (Step S3075).

In a case where the calculating unit 13 determines that the processes of Steps S3072-S3074 have not been performed on all log management data 80D (No in Step S3075), the calculating unit 13 returns to the process of Step S3071 (process of determining temporary storage of log management data including a device status content having a value “start”) and continues to perform the processes of Steps S3072-S3074. In other words, the calculating unit 13 repeats the processes in Steps S3072-S3074 until the process of Step S3071 is performed on all log management data 80D identified in Step S3071.

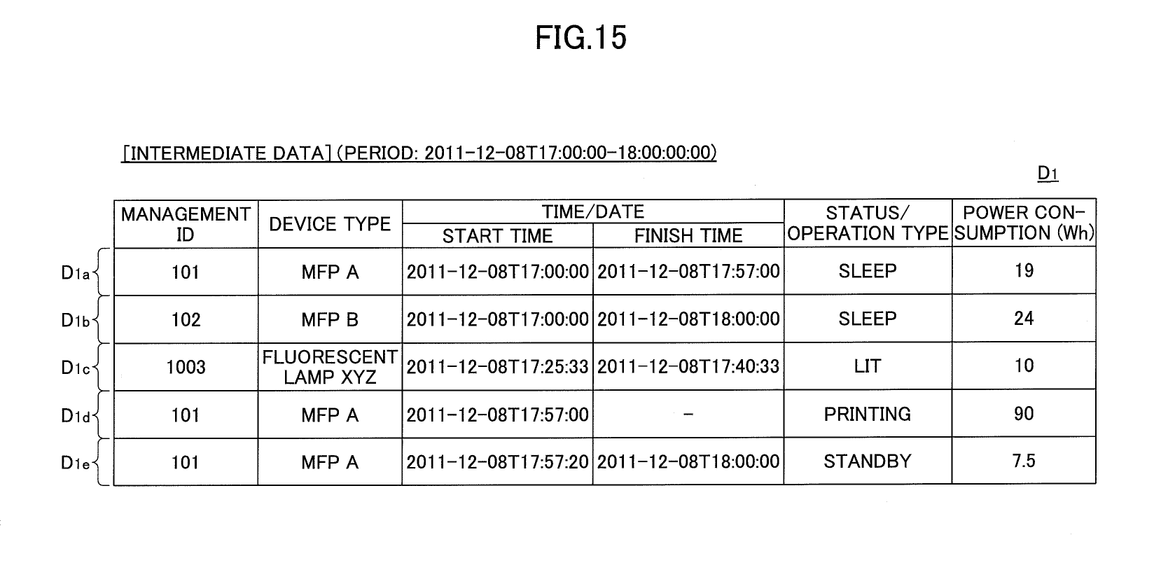

Accordingly, based on the compiled data of the power consumption amount of device status/device operation during the report period, the calculating unit 13 generates the intermediate data as illustrated in FIG. 15.

FIG. 15 is a schematic diagram illustrating a configuration of intermediate data D1 of the use of a currently used electronic device according to an embodiment of the present invention. FIG. 15 illustrates an example of intermediate data D1 generated by the calculating unit 13 according to the management data 80D of FIG. 6 and the power consumption management data 70D of FIG. 7 in a case where the input report period is indicated as “2011-12-08717:00:00-18:00:00”.

For example, the calculating unit 13 generates intermediate data D1a with respect to a status log “sleep” of device type “MFP A” recorded in the log management data 80D by performing the processes in Steps S3058 and S3059. Further, the calculating unit 13 generates intermediate data Dlb with respect to a status log “sleep” of device type “MFP B” recorded in the log management data 80D by performing the processes in Steps S3058 and S3059. Further, the calculating unit 13 generates intermediate data D1c with respect to a status log “lit” of device type “fluorescent lamp XYZ” recorded in the log management data 80D by performing the processes in Steps S3056 and S3057. Further, the calculating unit 13 generates intermediate data Dld with respect to an operation log “printing” of device type “MFP A” recorded in the log management data 80D by performing the processes in Steps S3042 and S3043. Further, the calculating unit 13 generates intermediate data Dle with respect to a status log “standby” of device type “MFP A” recorded in the log management data 80D by performing the processes in Steps S3073 and S3074.

Next, the above-described process performed in Step S308 of FIG. 11 is described in detail with the following example. In the following example, it is assumed that the intermediate data D1 of FIG. 15 has been generated.

### <<Generating of Report>>

FIG. 16 is a flowchart illustrating an example of the process of generating a report of Step S308.

The report generating unit 15 sorts the intermediate data D1 into groups of device types based on item “device type” of the intermediate data D1 (Step S3081).

For example, the intermediate data D1 illustrated in FIG. 15 includes intermediate data D1a-D1e corresponding to device types “fluorescent lamp XYZ”, “MFP A”, and “MFP B”. The device types are sorted into groups as follows.

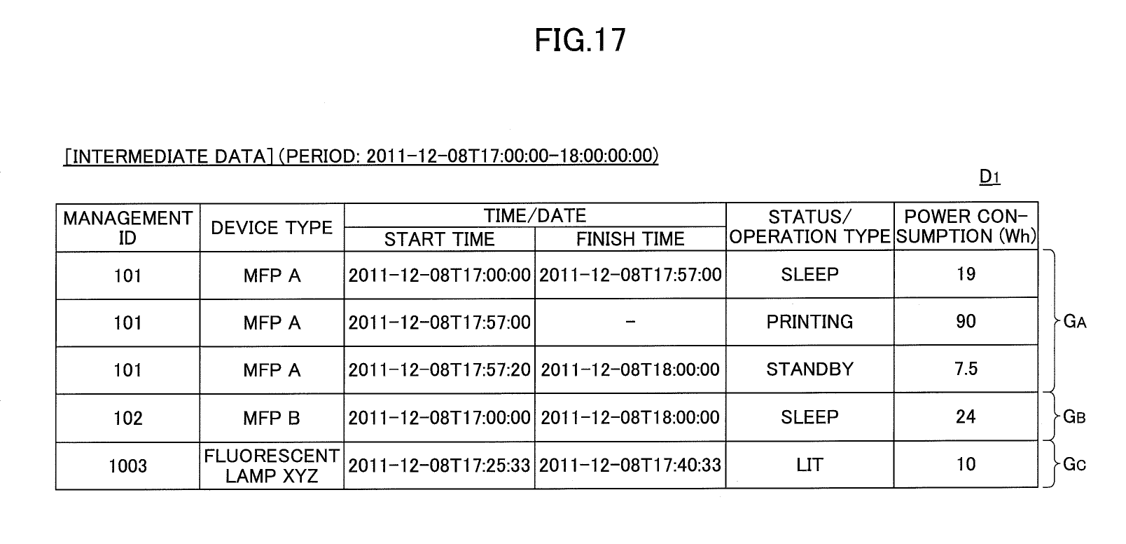

FIG. 17 is a schematic diagram illustrating an example where intermediate data D1 of the use of a currently used electronic device is sorted into groups.

FIG. 17 illustrates each of the device types “fluorescent lamp XYZ”, “MFP A”, and “MFP B” of the intermediate data D1 being sorted into 3 intermediate data groups GA, GB, and GC.

Returning to FIG. 16, the report generating unit 15 adds the values of calculated power consumption amount in group units [Zx=Zx1+ . . . +Zxn] (Step S3082).

For example, in a case of the intermediate data group GA of device type “MFP A”, the total of the added power consumption amount is [116.5=19+90+7.5] based on the values of the calculated power consumption amount of “19 (Wh)”, “90 (Wh)”, and “7.5 (Wh)”. Further, in a case of the intermediate data group GB of device type “MFP B”, the total of the added power consumption amount is [24] based on the value of the calculated power consumption amount of “24 (Wh)”. Further, in a case of the intermediate data group GC of device type “fluorescent lamp XYZ”, the total of the added power consumption amount is [10] based on the value of the calculated power consumption amount of “10 (Wh)”.

Then, the report generating unit 15 generates a visible report file by rendering (i.e., predetermined visual data obtained by processing the total value [Zx]) (Step S3083). In Step S3083, the report generating unit 15 generates a data file (e.g., table, graph) based on “management ID”, “device type”, the total value [Zx] of “power consumption” of the intermediate data D1.

Thereby, the report generating unit 15 can generate a report file (propose data) indicating the use of a currently used electronic device 200 as illustrated in FIG. 17 based on intermediate data D1 of the use of a currently used electronic device 200.

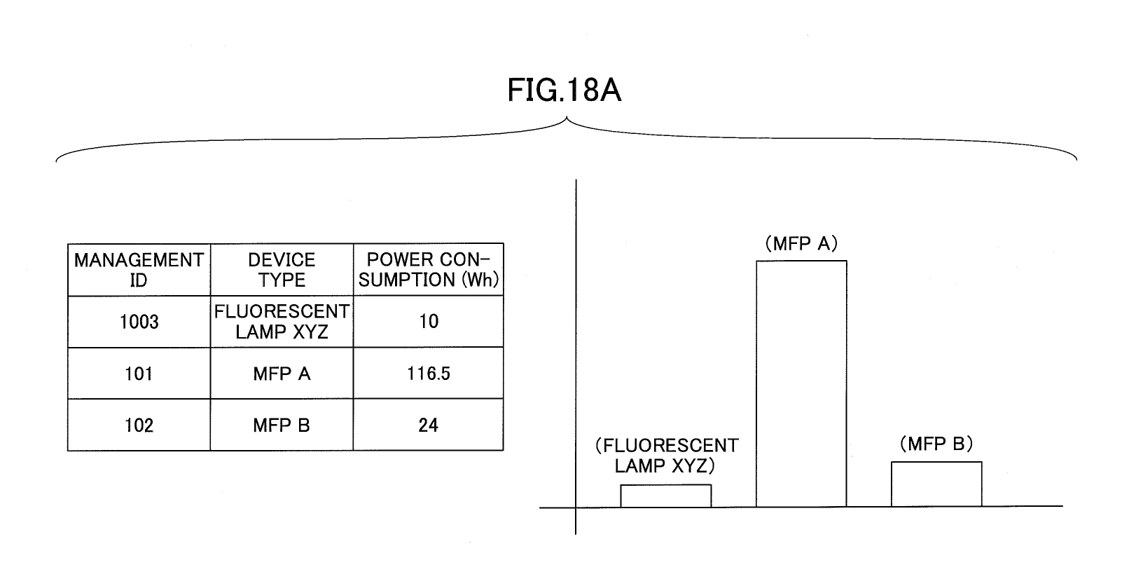

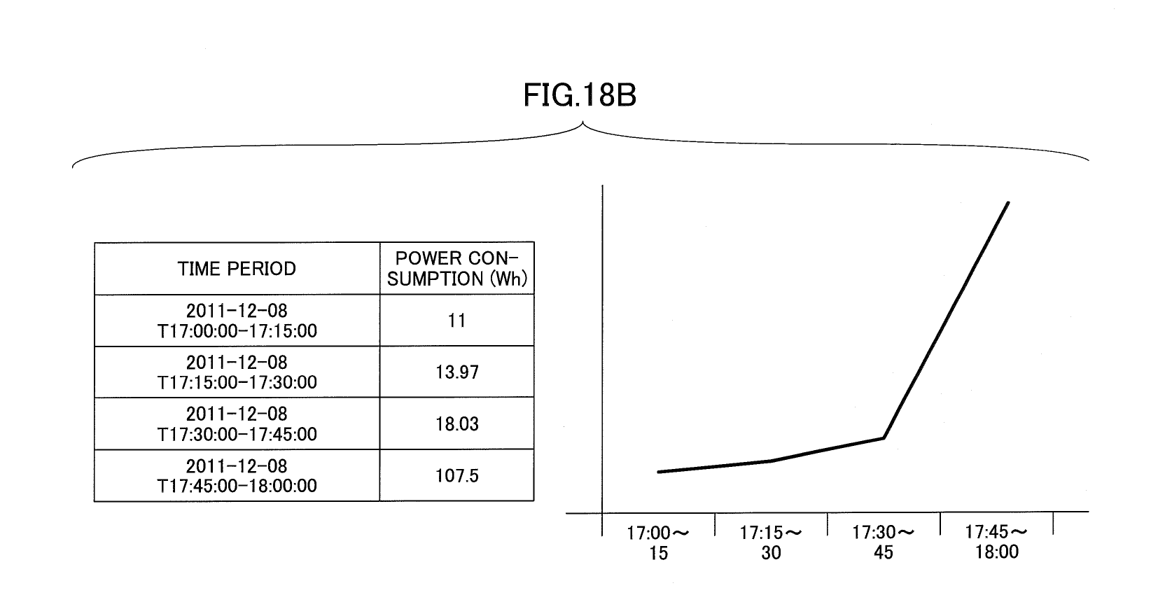

FIGS. 18A and 18B are schematic diagrams illustrating examples of data of a report of the use of a currently used electronic device 200 according to an embodiment of the present invention. FIG. 18A illustrates a case where the total of the power consumption amount corresponding to each device type falling within the report period is calculated based on the intermediate data D1 of FIG. 17, and a report of a table or a graph is generated based on the calculated total. FIG. 18B illustrates a case where the total of the power consumption amount corresponding to each time period falling within the report period is calculated based on the intermediate data D1 of FIG. 17, and a report of a table or a graph is generated based on the calculated total. As illustrated in FIG. 18B, the intermediate data D1 not only can be sorted into groups of device types but may also be sorted into groups of time periods. In the case of FIG. 18B, the report generating unit 15 sorts the intermediate data D1 into groups of time periods based on item “time/date” of the intermediate data D1.

### <<Basic Process of Performing Simulation>>

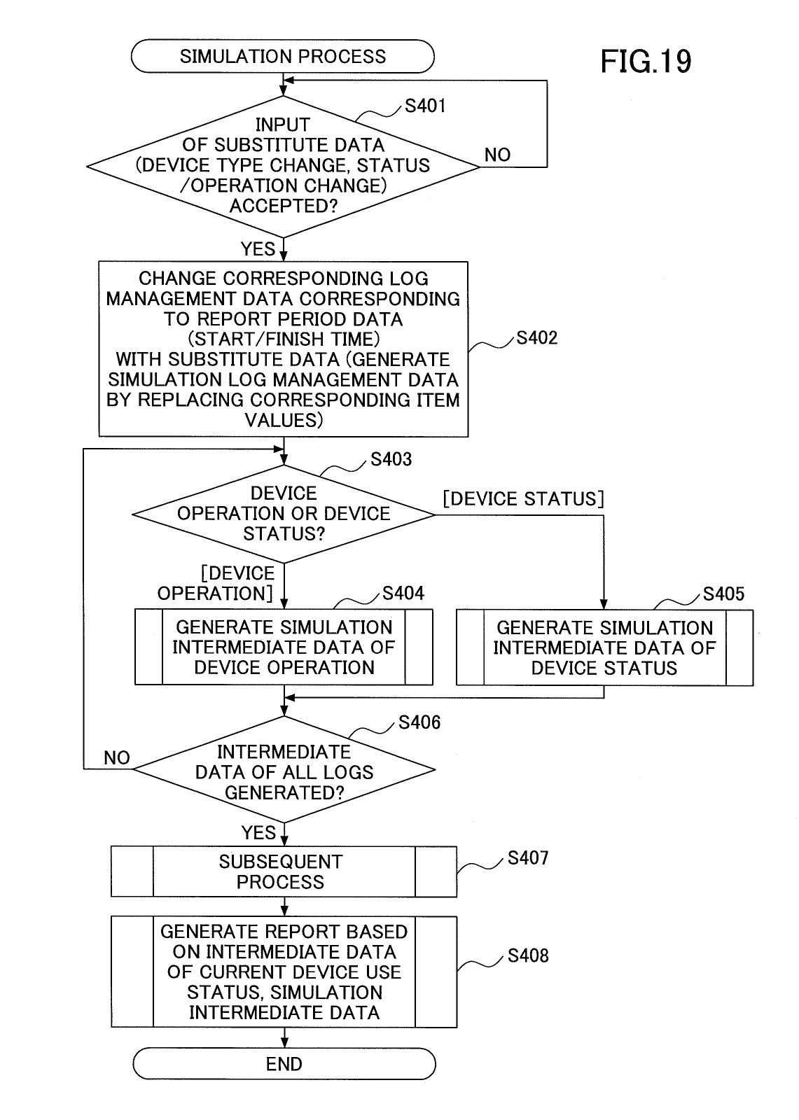

FIG. 19 is a flowchart illustrating procedures of a simulation process according to an embodiment of the present invention. The simulation process of FIG. 19 is performed by the calculating unit 13, the simulating unit 14, and the report generating unit 15. The simulation process of FIG. 19 is assumed to be performed after the above-described generation of a report of the use of a currently used electronic device 200. Further, because the simulation process is substantially the same as the basic report generating process of FIG. 11, the simulation process is described mainly on the differences with the report generating process.

The simulating unit 13 accepts input of a substitute data (e.g., device type change, status/operation change) by way of a predetermined interface (Yes in Step S401).

Then, the simulating unit 13 changes log management data 80D corresponding to a report period with a substitute data (Step S402). That is, the log management data 80D falling within a report period is substituted with substitute data. In Step S402, the simulating unit 14 generates simulation log management data 81D by replacing item values of the log management data 80D with corresponding item values of the input substitute data.

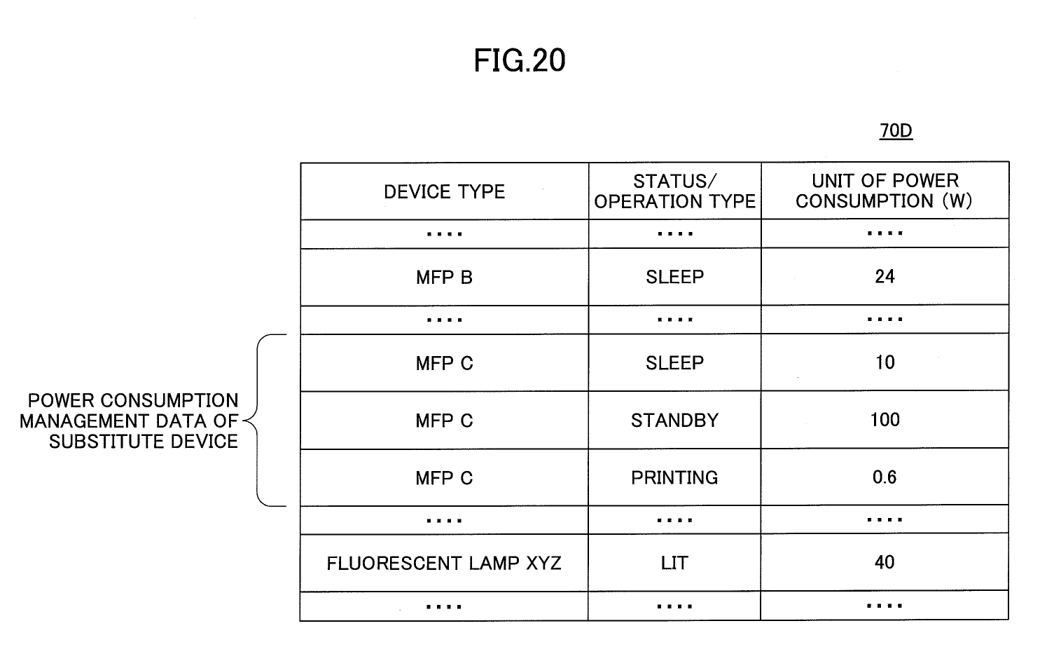

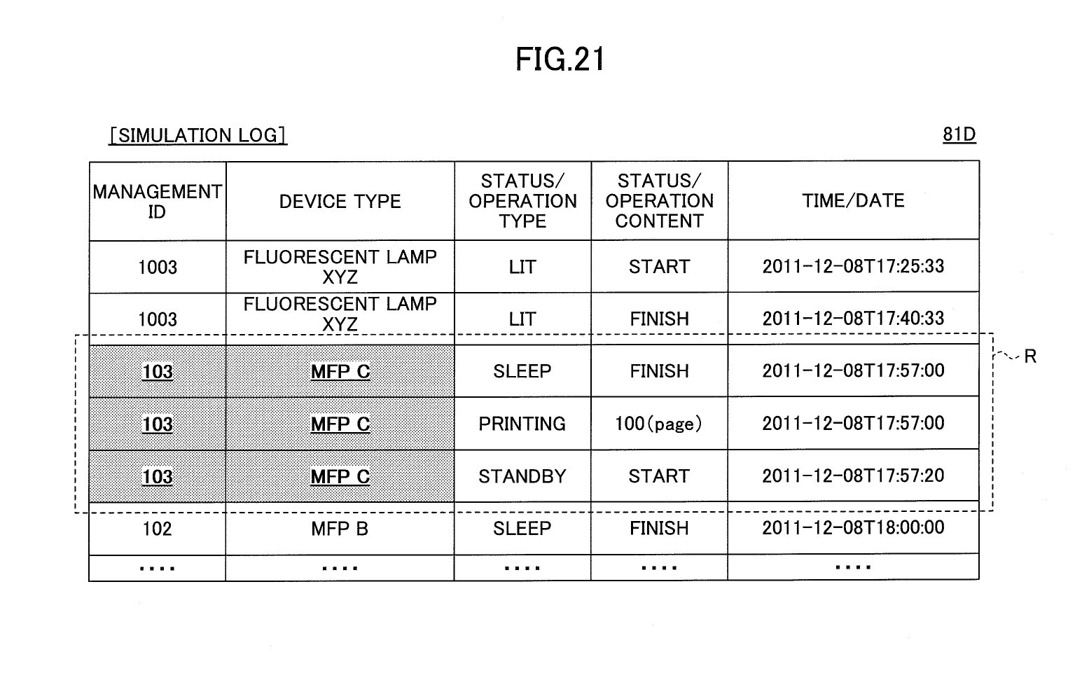

FIG. 20 is a schematic diagram illustrating a configuration of power consumption management data 70D (example 2) according to an embodiment of the present invention. FIG. 21 is a schematic diagram illustrating a configuration of simulation log management data 81D according to an embodiment of the present invention.

For example, in a case where the simulating unit 14 accepts input of substitute data (device type change) indicating that device type “MFP A” be substituted with device type “MFP C” based on the power consumption management data 70D of FIG. 20, the simulation log management data 81D of FIG. 21 is generated by replacing the values of “management ID” and “device type” recorded in status/operation logs of device type “MFP A” of the log management data 80D with values “103” and “MFP C” of the substitute data.

Returning to FIG. 19, the calculating unit 13 determines whether the “status/operation type” of the generated simulation log 81D is a value indicating “device operation” or “device status” (Step S403).

In a case where the calculating unit 13 determines that the “status/operation type” of the simulation log management data 81D is a value indicating “device operation” (“Device operation” in Step S403), the calculating unit 13 generates intermediate data D2 of a device operation that falls within the report period (i.e., intermediate data of the use of a substitute electronic device) (Step S404). The process of generating the intermediate data D2 of the device operation is substantially the same as the process of generating intermediate data illustrated in FIG. 12.

In a case where the calculating unit 13 determines that the “status/operation type” of the simulation log management data 81D is a value indicating “device status” (“Device status” in Step S403), the calculating unit 13 generates intermediate data D2 of a device status that falls within the report period in a case where a target electronic device 200 is substituted with a substitute electronic device (Step S405). The process of generating the intermediate data D2 of the device status is substantially the same as the process of generating intermediate data illustrated in FIG. 13.

Then, the calculating unit 13 determines whether the process of Step S404 or Step S405 has been performed on all simulation log management data 81D (i.e., all simulation logs falling within the report period) generated in Step S402 (Step S406).

In a case where the calculating unit 13 determines that the process of Step S404 or Step S405 has not been performed on all simulation log management data 81D (No in Step S406), the calculating unit 13 returns to the process of Step S403 (process of determining status/operation type) and continues to determine whether the process of Step S404 or Step S405 has been performed on simulation log management data 81D that have not been executed. In other words, the calculating unit 13 repeats the processes in Steps S403-S406 until the process of Step S404 or Step S405 is performed on all simulation log management data 81D generated in Step S402.

In a case where the calculating unit 13 determines that the process of Step S404 or Step S405 has been performed on all simulation log management data 81D (Yes in Step S406), the calculating unit 13 performs a subsequent process (Step S407). The subsequent process in a case of performing the simulation process is substantially the same as the subsequent process illustrated in FIG. 14.

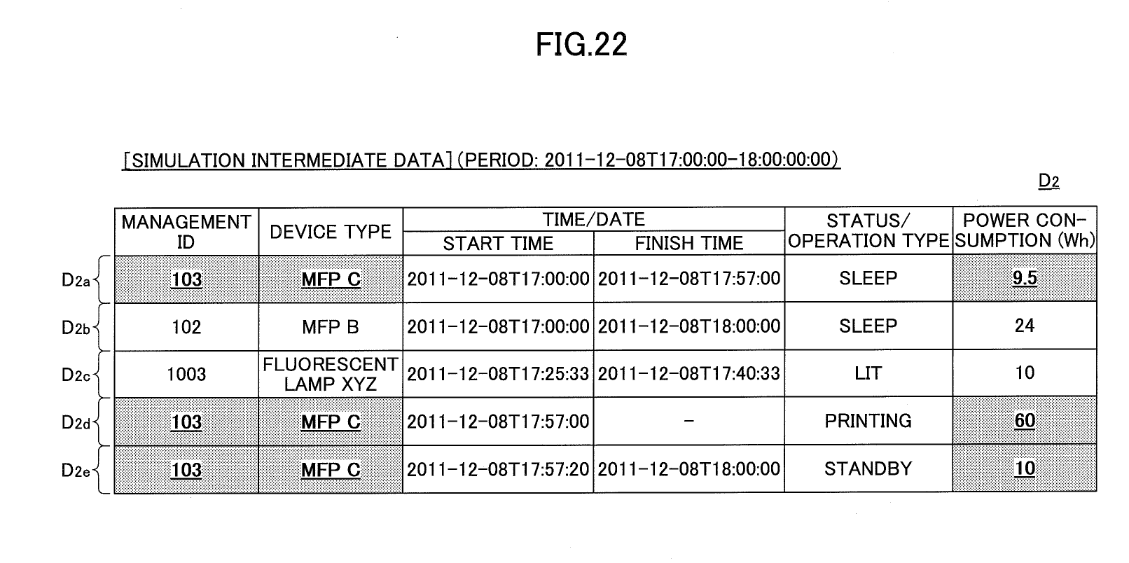

Accordingly, based on the compiled data of the power consumption amount of device status/device operation during the report period after substitution, the calculating unit 13 generates simulation intermediate data D2 as illustrated in FIG. 22.

FIG. 22 is a schematic diagram illustrating a configuration of simulation intermediate data D2 according to an embodiment of the present invention.

In a case where the simulating unit 14 accepts input of substitute data indicating substitute device type “MFP C”, the calculating unit 13 generates the simulation intermediate data D2 illustrated in FIG. 22 based on the simulation log management data 81D of FIG. 21 and the power consumption management data 70D of FIG. 20.

For example, with reference to FIG. 22, the intermediate data D2a is generated by performing the processes of Steps S3058 and S3059 on status log “sleep” of the substituting device type “MFP C” of the simulation log management data 81D. Further, the intermediate data D2b is generated by performing the processes of Steps S3058 and S3059 on status log “sleep” of the substituting device type “MFP B” of the simulation log management data 81D. Further, the intermediate data D2c is generated by performing the processes of Steps S3056 and S3057 on status log “lit” of the substituting device type “fluorescent lamp XYZ” of the simulation log management data 81D. Further, the intermediate data D2d is generated by performing the processes of Steps S3042 and S3043 on operation log “printing” of the substituting device type “MFP C” of the simulation log management data 81D. Further, the intermediate data D2e is generated by performing the processes of Steps S3073 and S3074 on status log “standby” of the substituting device type “MFP C” of the simulation log management data 81D.

Returning to FIG. 19, the report generating unit 15 generates a report based on the intermediate data D1 (i.e., intermediate data of the use of the currently used electronic device) and the simulation intermediate data D2 (i.e., intermediate data of the use of the substitute electronic device) generated by the calculating unit 13 (Step S408).

That is, in Step S408, the report generating unit 15 generates a report file (propose data) that allows visual comparison between the power consumption amount at the time of using the target electronic device 200 and the power consumption amount at the time of using the substitute electronic device 200 in the entire user environment (i.e., predetermined processed data that allows comparison between the current power consumption amount and the current power consumption amount after simulation).

Thereby, the report generating unit 15 can generate a report file (proposal data) that allows visual comparison between the power consumption amount before and after the substitution of the currently used electronic device in the entire user environment. The generated report file may be used as data to be proposed to, for example, the user of the management apparatus 100.

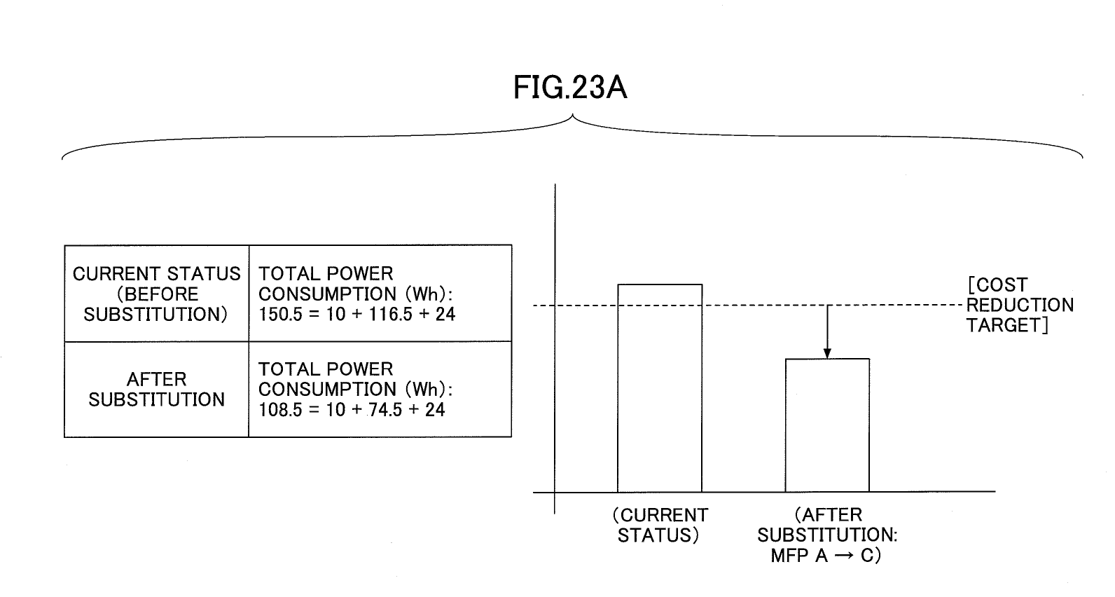

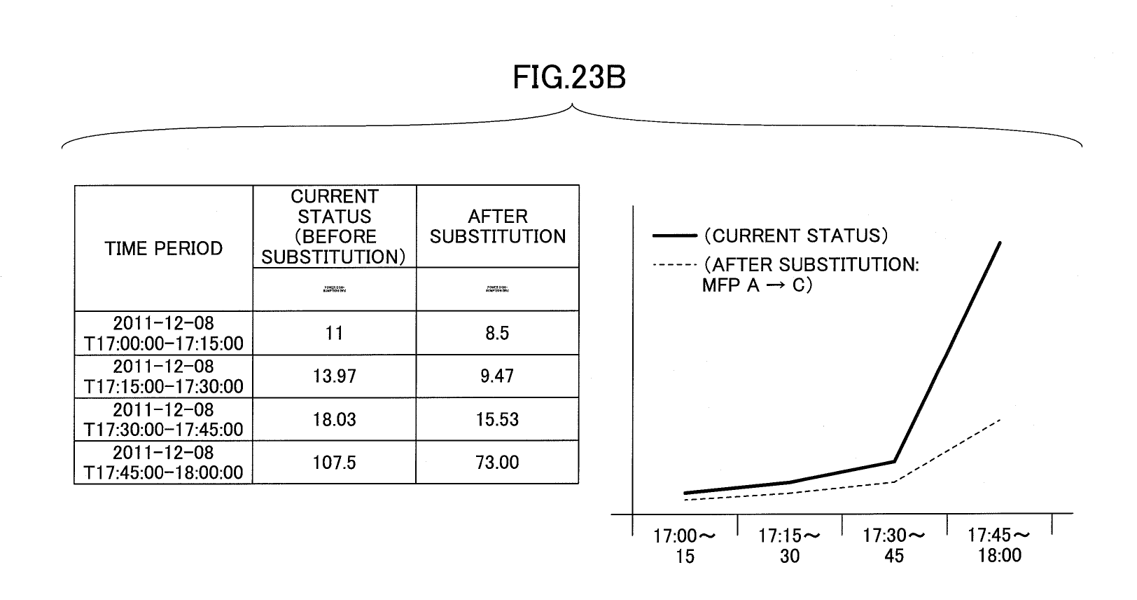

FIGS. 23A and 23B are schematic diagram illustrating examples of data of a report before and after substitution according to an embodiment of the present invention. FIG. 23A illustrates a case where the total of the power consumption amount of a current status during the report period (before substitution) and the total of the power consumption amount during the report period after substitution are calculated, and a report of a table or a graph is generated based on the calculated totals. The calculation in the case of FIG. 23A is based on the intermediate data D1 (intermediate data of the user of the currently used electronic device) of FIG. 15 and the simulation intermediate data D2 (intermediate data of the use of the substitute electronic device) of FIG. 22. Therefore, the effect of cost reduction (indicated with arrow extending below cost reduction target) by substitution can be visually confirmed by proposing a value of a cost reduction target (indicated with broken line in FIG. 23A) with the report of FIG. 23A.

FIG. 23B illustrates a case where the total of the power consumption amount of a current status during the report period (before substitution) and the total of the power consumption amount during the report period after substitution are calculated in correspondence with time period (time period of use), and a report of a table or a graph is generated based on the calculated totals. The calculation in the case of FIG. 23B is based on the intermediate data D1 (intermediate data of the user of the currently used electronic device) of FIG. 15 and the simulation intermediate data D2 (intermediate data of the use of the substitute electronic device) of FIG. 22. Therefore, a time period exhibiting effective cost reduction owing to substitution of the used electronic device (in this example, a time period ranging from 17:45 to 18:00) can be visually confirmed.

Hence, the management apparatus 100 can substitute a data item of a log recorded during a report period with a corresponding item of substitute data (replacement of values of data) by based on substitute data such as data indicating “device type change” or “status/operation change”. Further, the management apparatus 100 can generate intermediate data D2 of the use of a substitute electronic device including the results of compiling the power consumption amount in correspondence with each device status/device operation falling within the report period after substitution. Further, the management apparatus 100 can generate/process data that allows visual comparison between the power consumption amount before and after the substitution of the currently used electronic device in the entire user environment based on the intermediate data D1 of the use of the currently used electronic device and the intermediate data D2 of the use of the substitute electronic device.

Hence, with the management apparatus 100 according to the above-described embodiment of the present invention, it can be understood how the electronic device 200 is being used in the entire user environment (e.g., how electric power is being consumed). Further, proposals on what to do for resolving problems pertaining to power consumption can be made.

### <Summary>

As described above, the log obtaining part 11 of the management apparatus 100 receives a status/operation log of the electronic device 200a and records the status/operation log in the second storage unit (log management data storage unit) 80. Further, the log generating unit 12 of the management apparatus 100 generates a status log of the electronic device 200b and records the generated status log in the second storage unit 80. Further, the calculating unit 13 of the management apparatus 100 calculates a power consumption amount (current status value) of a currently used electronic device during a predetermined period. Further, the simulating unit 14 simulates a case of substituting a target electronic device 200 with a substitute electronic device 200 capable of achieving a device status recorded in a log or capable of executing a device operation recorded in a log and achieving the device status or executing the device operation with the substitute electronic device 200 instead of using the target electronic device 200. In the simulation, the calculating unit 13 of the management apparatus 100 calculates an estimated power consumption amount (estimate value) of the use of the substitute electronic device 200 during a predetermined period. As a result, the report generating unit 15 of the management apparatus 100 generates a report that allows visual comparison between a power consumption amount of the use of the currently used electronic device (target electronic device) 200 during a predetermined period and an estimated power consumption amount of the use of the substitute electronic device 200 during a predetermined period in an entire user environment, so that the report can be provided to the user.

Accordingly, the management apparatus according to the above-described embodiment of the present invention can provide an optimum proposal for achieving cost reduction in view of the use of electronic devices in an entire user environment and visually comprehend the use of electronic devices in the entire user environment. As a result, the user can specifically understand what needs to be improved in the entire user environment for achieving cost reduction. Thereby, the user can take appropriate effective measures to achieve cost reduction.

The above-described management function is achieved by using a program encoded with a programming language matching a platform of the management apparatus 100 and executing the program with the CPU 106 of the management apparatus 100.

The program may be recorded in the computer-readable recording medium 103a. Thereby, the program can be installed in the management apparatus 100 via the external I/F 103. Further, because the management apparatus 100 also includes the communications I/F 107, the program may be downloaded from a telecommunication line and installed in the management apparatus 100.

### Modified Example 1

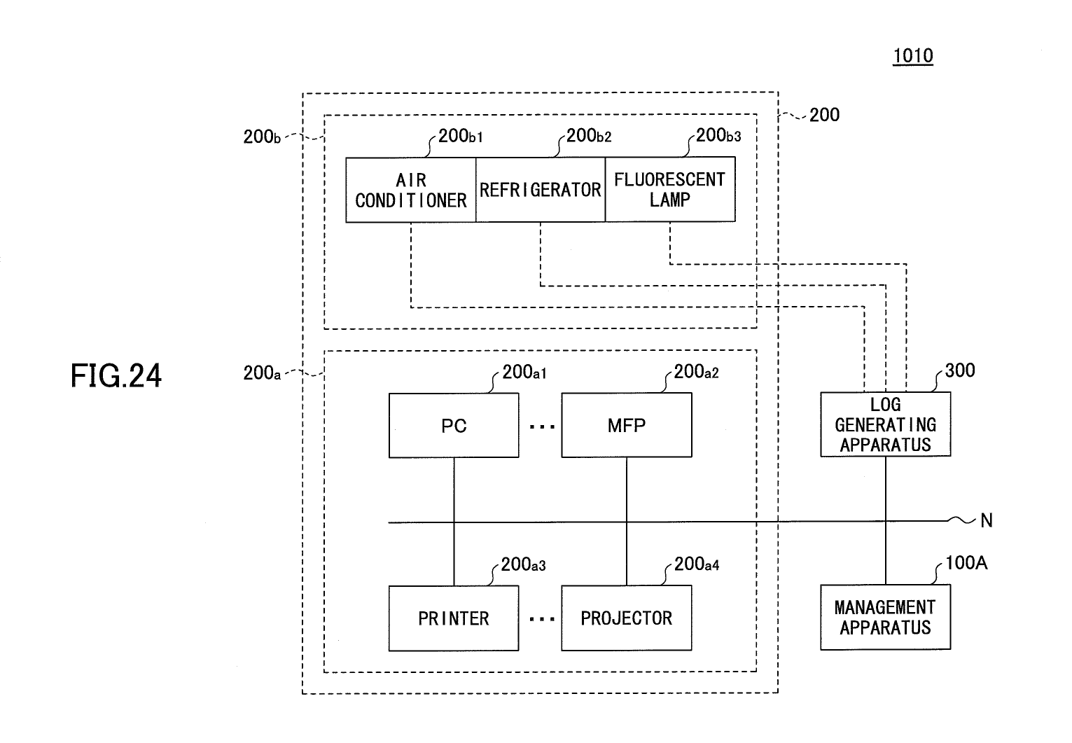

FIG. 24 is a schematic diagram illustrating an example of a configuration of a management system 1010 according to the modified example 1. The configuration of the system 1010 of FIG. 24 has one or more electronic devices 200, a management apparatus 100A, and a log generating apparatus 300 that are connected to each other by a data transfer path N.

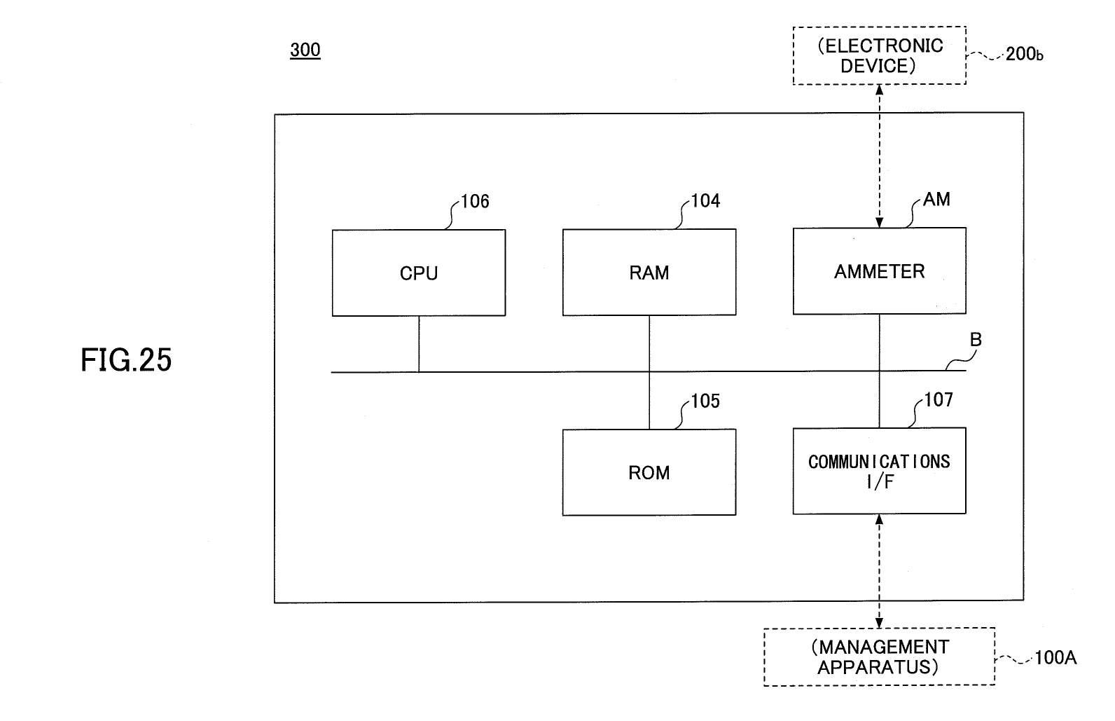

The log generating apparatus 300 includes a log generating function (log generating unit). The log generating apparatus 300 has a hardware configuration as illustrated in FIG. 25.

FIG. 25 is a schematic diagram illustrating a hardware configuration of the log generating apparatus 300 according to an embodiment of the present invention. As illustrated in FIG. 25, the log generating apparatus 300 basically has the same configuration as the management apparatus 100 of FIG. 2. However, the log generating apparatus 300 has an ammeter AM corresponding to each electronic device 200b for detecting changes of electric current of each electronic device 200b. As described above, the electronic device 200b is unable to notify (transmit) a status/operation log (history data) pertaining to the electronic device 200b by the electronic device 200b itself. Further, the log generating apparatus 300 includes a communications I/F 107 for transmitting generated log data to the management apparatus 100A.

The log generating function of the log generating apparatus 300 having the above-described configuration is performed by loading a program (to be installed in the log generating apparatus 300) from a storage device (e.g., ROM 105) to a memory (e.g., RAM 104) and executing the program with an operation device (e.g., CPU 106). The program to be installed in the log generating apparatus 300 is software for executing the log generating function.

Returning to FIG. 24, the management system 1010 uses the above-described electronic device 200, the management apparatus 100A, and the log generating apparatus 300 to provide the following service.

The management apparatus 100A records a status/operation log of the electronic device 200 in a predetermined storage area. In a case where the electronic device 200 is the electronic device 200a, the management apparatus 100A stores log data received from the electronic device 200a. In a case where the electronic device 200 is the electronic device 200b, the log generating apparatus 300 confirms the status/operation of the electronic device 200b. In a case where the log generating apparatus 300 confirms a change in the status/operation of the electronic device 200b, the log generating apparatus 300 generates log data of the electronic device 200b corresponding to the change and transmits the generated log data to the management apparatus 100A. Then, the management apparatus 100A, receiving the generated log data, stores (records) the received log data therein.

In other words, the management apparatus 100A according to the modified example 1 receives log data of the electronic device 200 directly from the electronic device 200 in a case where the electronic device 200 is an electronic device 200a capable of notifying (transmitting) a status/operation log (history data) pertaining to the electronic device 200a by the electronic device 200a itself. On the other hand, the management apparatus 100A according to the modified example 1 receives log data of the electronic device 200 via the log generating apparatus 300 in a case where the electronic device 200 is an electronic device 200b unable to notify (transmit) a status/operation log (history data) pertaining to the electronic device 200b by the electronic device 200b itself.

Then, in a case where the management apparatus 100A accepts an input (designation) of a report period (input period data) by way of a predetermined interface, the management apparatus 100A calculates the power consumption amount (current status value) of a currently used electronic device 200 during the report period (designated period). Further, in a case where the management apparatus 100A accepts an input (designation) of a substitute electronic device 200 capable of attaining a device status recorded in a log or capable of executing a device operation recorded in a log, the management apparatus 100A performs the following processes. That is, the management apparatus 100A estimates (simulates) a case of substituting a target electronic device 200 with a substitute electronic device 200 capable of achieving a device status recorded in a log or capable of executing a device operation recorded in a log and achieving the device status or executing the device operation with the substitute electronic device 200 instead of using the target electronic device 200. The management apparatus 100A calculates an estimated power consumption amount (estimate value) of the use of the substitute electronic device 200 during the report period.

As a result, the management apparatus 100A generates a visually comparable report that allows comparison between the power consumption amount of the use of the currently used electronic device during the report period and the estimated power consumption amount of the use of the substitute electronic device 200 during the report period in the entire user system. Accordingly, the generated report can be displayed on a screen of, for example, the user's PC (data terminal) 200a1 in response to a request from the user's PC 200a1.

### <Management Function>

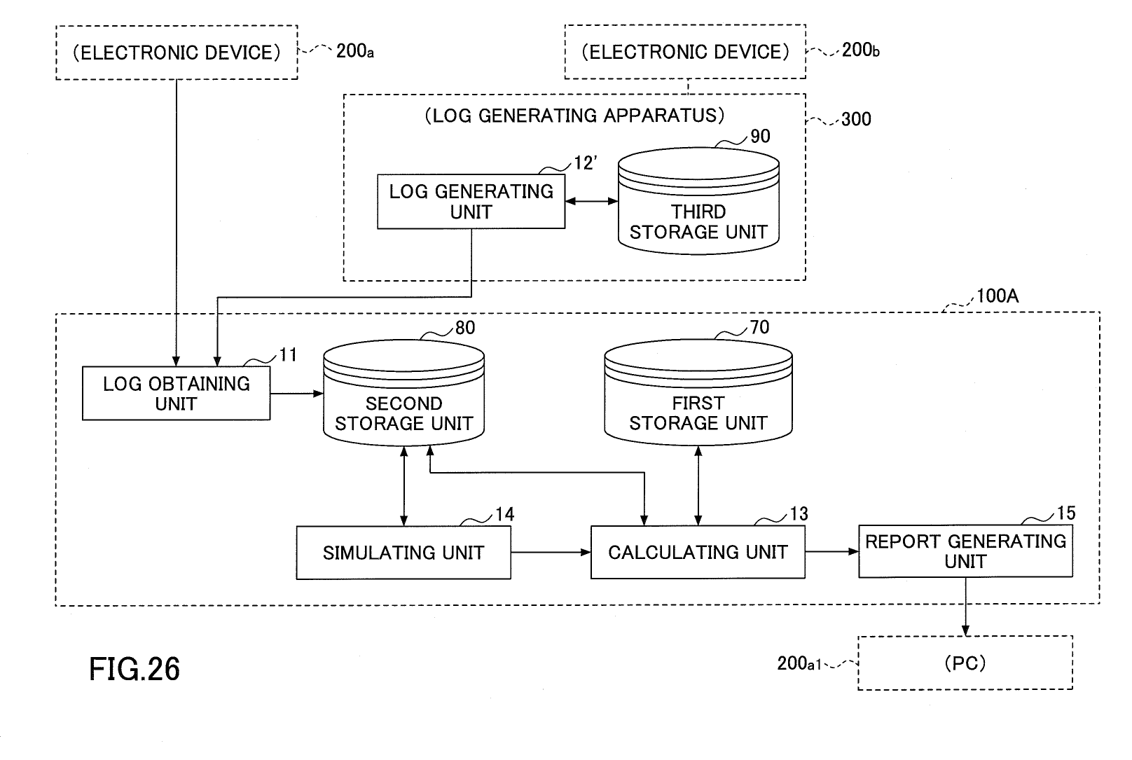

FIG. 26 is a schematic diagram illustrating a configuration for executing a management function according to the modified example 1. As illustrated in FIG. 26, a log generating unit 12′ is included in the log generating apparatus 12. The log generating unit 12′ monitors the electronic device 200b. In a case where a change of status/operation is detected according to the results of the monitoring (monitoring results), the log generating unit 12′ generates log data corresponding to the detected change of status/operation.

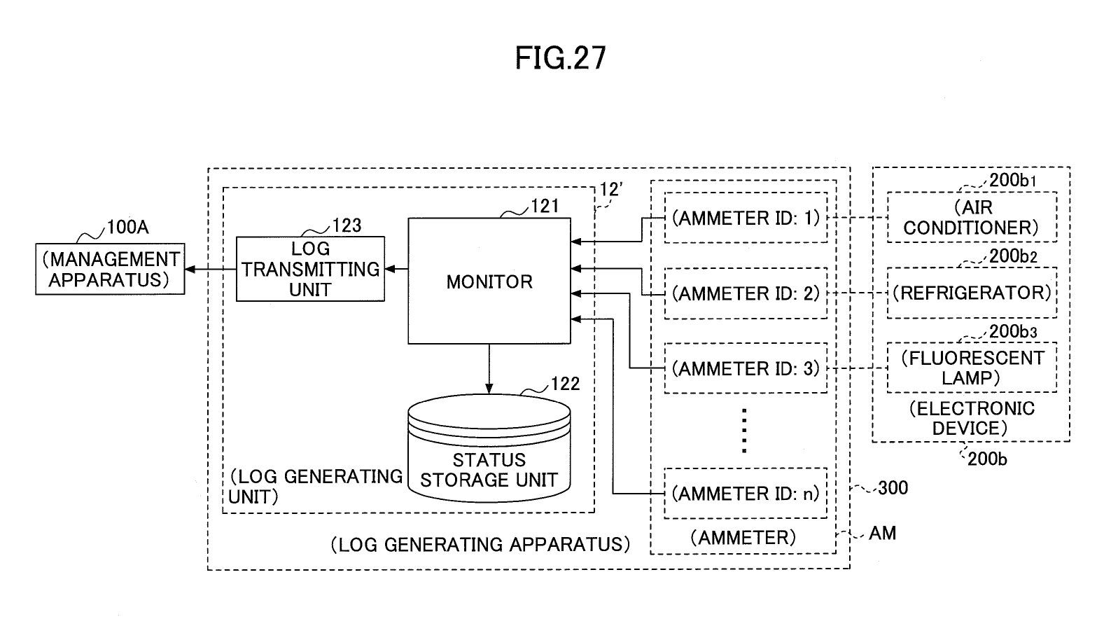

The operation of the log generating unit 12′ is performed by the below-described function parts of FIG. 27 and the use of the device management data 90D.

FIG. 27 is a schematic diagram illustrating a configuration of the log generating unit 12′ according to the modified example 1. As illustrated in FIG. 27, the log generating unit 12′ includes a monitor 121, a status storage unit 122, and a log transmitting unit 123. The monitor 121 monitors changes of current of the electronic device 200b by obtaining the current value from each ammeter AM. When the monitor 121 detects a change of current, the monitor 121 refers to the ammeter management data 90D1 and identifies the corresponding relationship between the electronic device 200b and the ammeter AM by which the current change is detected. Thereby, the monitor 121 obtains the device type of a corresponding electronic device 200b. Then, the monitor 121 refers to the status management data 90D2 based on the obtained device type data and identifies a corresponding relationship between the electric current value and status of the corresponding electronic device 200b. Thereby, the monitor 121 obtains a status data corresponding to the electric current data having a value nearest to the electric current value detected by the ammeter AM (monitoring result). The monitor 121 determines whether the current status is a status prior to the change of the detected change of electric current by referring to the obtained status data (current status) and the status data (status prior to change of electric current) detected from the corresponding electronic device 200b in a previous monitoring process. In a case where the monitor 121 determines that the status of the electronic device 200b has changed, log data is generated. The generated log data includes, for example, the device type of the corresponding electronic device 200b, the identifier of the corresponding electronic device 200b, and the status content of the corresponding electronic device 200b. Then, the log transmitting unit 123 transmits the generated log data to the management apparatus 100A.

Accordingly, the log generating unit 12′ uses the functions of the monitor 121 and the log transmitting unit 123 and the device management data 90D to perform the following process. That is, the log generating unit 12′ generates log data of the electronic device 200b from which status change is detected and transmits the generated log data to the management device 100A.

Returning to FIG. 26, the log obtaining unit 11 of the management apparatus 100A receives log data from the electronic device 200a and stores the log data including a status/operation log of the electronic device 200a in the second storage unit 80. Further, the log obtaining unit 11 of the management apparatus 100A receives log data generated by the log generating unit 12′ and stores the log data including a status/operation log of the electronic device 200b in the second storage unit 80. Thereby, a new data set corresponding to the log data is generated in the log management data 80D, and the status/operation log of the electronic device 200 is recorded in an order of, for example, the time (temporal order) in which the status has changed or the time (temporal order) in which the operation has been executed.

As described above, the log obtaining part 11 of the management apparatus 100A receives a status/operation log of the electronic device 200a and records the status/operation log in the second storage unit (log management data storage unit) 80. Further, the log obtaining unit 11 of the management apparatus 100A receives a status log of the electronic device 200b from the log generating apparatus 300 and records the generated status log in the second storage unit 80. Further, the calculating unit 13 of the management apparatus 100A calculates a power consumption amount (current status value) of a currently used electronic device during a predetermined period. Further, the simulating unit 14 simulates a case of substituting a target electronic device 200 with a substitute electronic device 200 capable of achieving a device status recorded in a log or capable of executing a device operation recorded in a log and achieving the device status or executing the device operation with the substitute electronic device 200 instead of using the target electronic device 200. In the simulation, the calculating unit 13 of the management apparatus 100A calculates an estimated power consumption amount (estimate value) of the use of the substitute electronic device 200 during a predetermined period. As a result, the report generating unit 15 of the management apparatus 100A generates a report that allows visual comparison between a power consumption amount of the use of the currently used electronic device (target electronic device) 200 during a predetermined period and an estimated power consumption amount of the use of the substitute electronic device 200 during a predetermined period in an entire user environment, so that the report can be provided to the user.

Accordingly, the management apparatus 100A of the modified example 1 can attain substantially the same effects as the management apparatus 100 according to the above-described embodiment of the present invention.

Further, in the management apparatus 100A of the modified example, the function of obtaining log data from the electronic device 200a (capable of notifying (transmitting) a status/operation log (history data) pertaining to the electronic device 200a by the electronic device 200a itself) and the function of generating log data of the electronic device 200b (unable to notify (transmit) a status/operation log (history data) pertaining to the electronic device 200b by the electronic device 200b itself) are performed by separate apparatuses. Thereby, work load can be decentralized and a system can be flexibly built. For example, with the modified example 1, the log generating apparatus 300 can be set on each floor of an office installation, so that a system communicable with the management apparatus 100A can be built. In a case where the log generating unit 12 is included in the management apparatus 100, all of the electronic devices 200b of an office installation are to be connected to the ammeter AM of the management apparatus 100. As a result, wiring of the electronic devices 200b becomes complicated. With the modified example 1, the electronic devices 200b can be distributed smaller numbers by setting the log generating apparatus 300 in multiple locations of the office installation. Thereby, complicated wiring can be avoided and a system can be flexibly built.

### Modified Example 2

Although the management apparatus 100 according to the above-described embodiment has a configuration including the log obtaining unit 11 and the log generating unit 12, the management apparatus 100 may be have other configurations. In the modified example 2, the log obtaining unit 11 and the log generating unit 12 are included in another apparatus.

### <System Configuration>

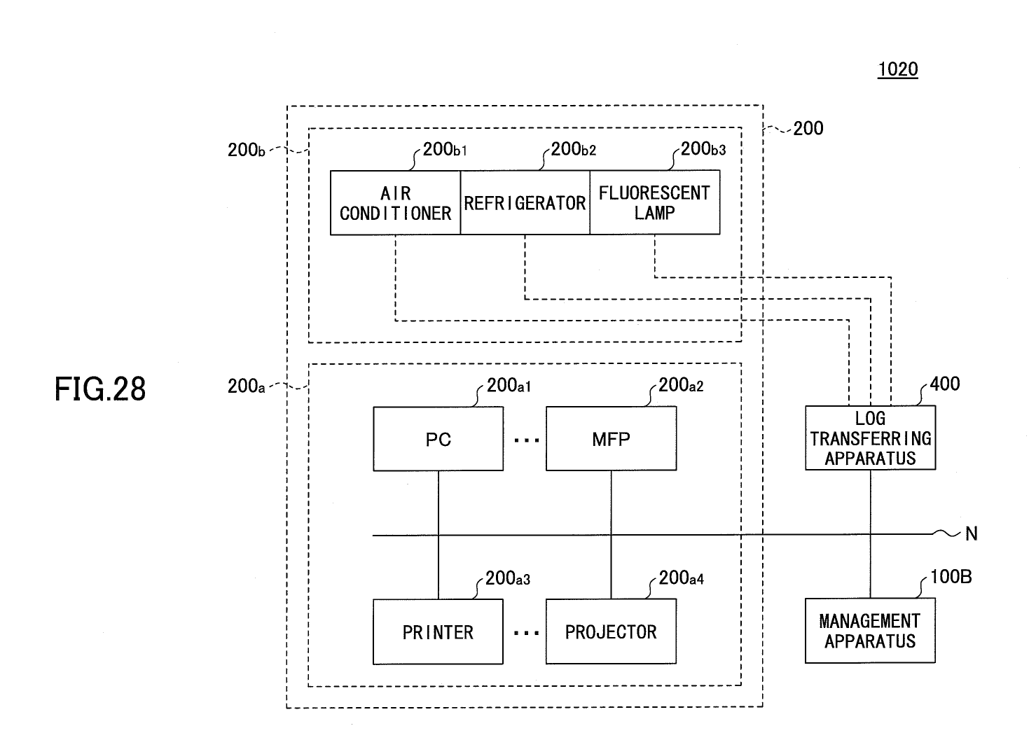

FIG. 28 is a schematic diagram illustrating an example of a configuration of a management system 1020 according to the modified example 2. The configuration of the system 1020 of FIG. 28 has one or more electronic devices 200, a management apparatus 100B, and a log transferring apparatus 400 that are connected to each other by a data transfer path N.

The log transferring apparatus 400 includes a log obtaining function (log obtaining unit) and a log generating function (log generating unit). The log transferring apparatus 400 has substantially the same hardware configuration as the hardware configuration of the log generating apparatus 300 illustrated in FIG. 25. The log obtaining function and the log generating function of the log transferring apparatus 400 having the above-described configuration are performed by loading a program (to be installed in the log transferring apparatus 400) from a storage device (e.g., ROM) to a memory (e.g., RAM) and executing the program with an operation device (e.g., CPU). The program to be installed in the log transferring apparatus 400 is software for executing the log obtaining function and the log generating function.

The management system 1020 uses the above-described electronic device 200, the management apparatus 100B, and the log transferring apparatus 400 to provide the following service.

The management apparatus 100B records a status/operation log of the electronic device 200 in a predetermined storage area. In a case where the electronic device 200 is the electronic device 200a, the log transferring apparatus 400 transfers log data received from the electronic device 200a. In a case where the electronic device 200 is the electronic device 200b, the log transferring apparatus 400 confirms the status/operation of the electronic device 200b. In a case where the log transferring apparatus 400 confirms a change in the status/operation of the electronic device 200b, the log transferring apparatus 400 generates log data of the electronic device 200b corresponding to the change and transfers the generated log data to the management apparatus 100B. Then, the management apparatus 100B, receiving the log data of the electronic device 200a, 200b transferred from the log transferring apparatus 400, stores (records) the received log data therein.

In other words, the management apparatus 100B according to the modified example 2 receives log data of the electronic device 200a, 200b by way of the log transferring apparatus 400.

Then, in a case where the management apparatus 100B accepts an input (designation) of a report period (input period data) by way of a predetermined interface, the management apparatus 100B calculates the power consumption amount (current status value) of a currently used electronic device 200 during the report period (designated period). Further, in a case where the management apparatus 100B accepts an input (designation) of a substitute electronic device 200 capable of attaining a device status recorded in a log or capable of executing a device operation recorded in a log, the management apparatus 100B performs the following processes. That is, the management apparatus 100B estimates (simulates) a case of substituting a target electronic device 200 with a substitute electronic device 200 capable of achieving a device status recorded in a log or capable of executing a device operation recorded in a log and achieving the device status or executing the device operation with the substitute electronic device 200 instead of using the target electronic device 200. The management apparatus 100B calculates an estimated power consumption amount (estimate value) of the use of the substitute electronic device 200 during the report period.

As a result, the management apparatus 100B generates a visually comparable report that allows comparison between the power consumption amount of the use of the currently used electronic device during the report period and the estimated power consumption amount of the use of the substitute electronic device 200 during the report period in the entire user system. Accordingly, the generated report can be displayed on a screen of, for example, the user's PC (data terminal) 200a1 in response to a request from the user's PC 200a1.

### <Management Function>

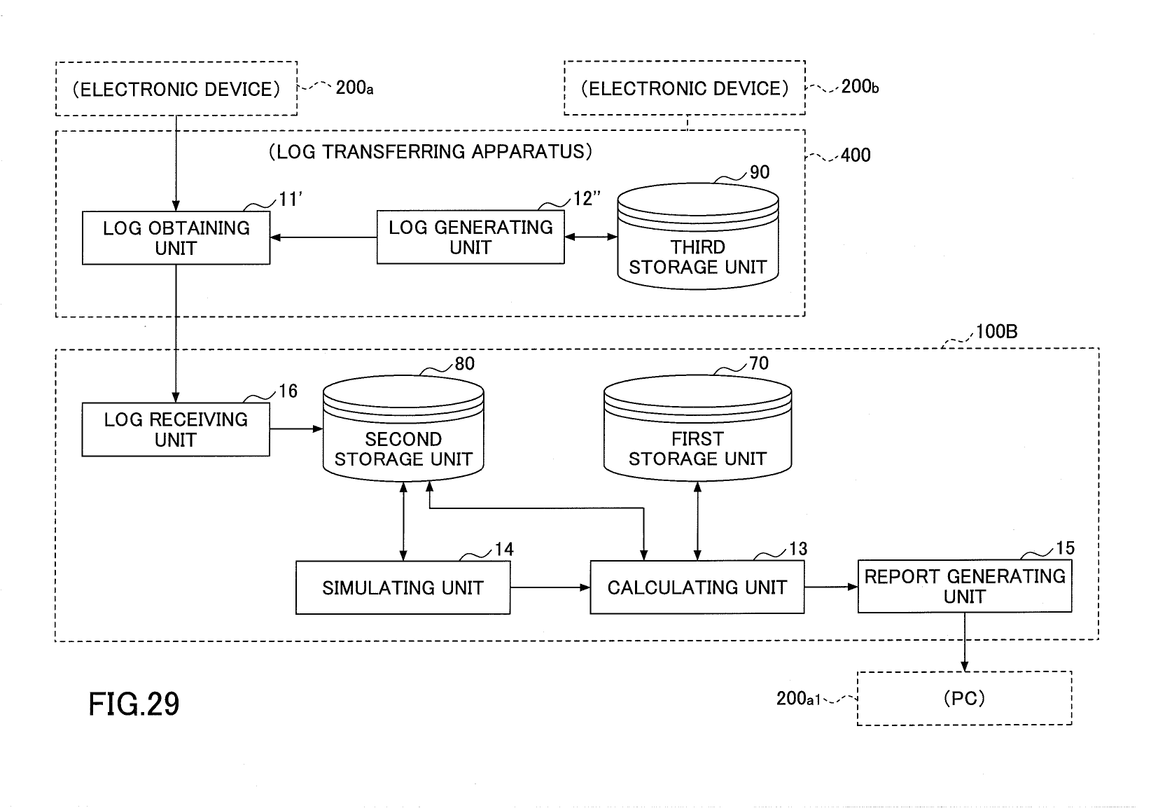

FIG. 29 is a schematic diagram illustrating a configuration for executing a management function according to the modified example 2. As illustrated in FIG. 29, a log obtaining unit 11′ and a log generating unit 12″ are included in the log transferring apparatus 400. The log obtaining unit 11′ obtains a status/operation log by receiving log data reported from the electronic device 200a. The log generating unit 12″ monitors the electronic device 200b. In a case where a change of status/operation is detected according to the results of the monitoring (monitoring results), the log generating unit 12″ generates log data corresponding to the detected change of status/operation. The log generating unit 12″ sends the generated log data to the log obtaining unit 11′. Accordingly, the log obtaining unit 11′ transfers (transmits) the obtained log data to the management apparatus 100B.

The management apparatus 100B includes a log receiving unit 16. The log receiving unit 16 receives a status/operation log of the electronic device 200 (i.e., 200a, 200b) transferred from the log transferring apparatus 400. The log receiving unit 16 receives log data from the electronic device 200 and stores the log data including a status/operation log of the electronic device 200 in the second storage unit 80. Thereby, a new data set corresponding to the log data is generated in the log management data 80D, and the status/operation log of the electronic device 200 (i.e., 200a, 200b) is recorded in an order of, for example, the time (temporal order) in which the status has changed or the time (temporal order) in which the operation has been executed.

As described above, the log receiving part 16 of the management apparatus 100B receives a status/operation log of the electronic device 200 (i.e., 200a, 200b) and records the status/operation log in the second storage unit (log management data storage unit) 80. Further, the calculating unit 13 of the management apparatus 100B calculates a power consumption amount (current status value) of a currently used electronic device during a predetermined period. Further, the simulating unit 14 simulates a case of substituting a target electronic device 200 with a substitute electronic device 200 capable of achieving a device status recorded in a log or capable of executing a device operation recorded in a log and achieving the device status or executing the device operation with the substitute electronic device 200 instead of using the target electronic device 200. In the simulation, the calculating unit 13 of the management apparatus 100B calculates an estimated power consumption amount (estimate value) of the use of the substitute electronic device 200 during a predetermined period. As a result, the report generating unit 15 of the management apparatus 100B generates a report that allows visual comparison between a power consumption amount of the use of the currently used electronic device (target electronic device) 200 during a predetermined period and an estimated power consumption amount of the use of the substitute electronic device 200 during a predetermined period in an entire user environment, so that the report can be provided to the user.

Accordingly, the management apparatus 100B of the modified example 2 can attain substantially the same effects as the management apparatus 100 according to the above-described embodiment of the present invention.

Further, in the management apparatus 100A of the modified example, the function of obtaining/generating log data from the electronic device 200 and the function of generating a report including a an optimizing data for achieving cost reduction in view of the use of electronic devices 200 in the entire user environment are performed by separate apparatuses. Thereby, work load can be decentralized and a system can be flexibly built. For example, with the modified example 2, the log transferring apparatus 400 can be set on each floor of an office installation, so that a system communicable with the management apparatus 100B can be built. In a case where the log obtaining unit 11 and the log generating unit 12 are included in the management apparatus 100, processes of all of the electronic devices 200b of an office installation are to be concentrated to the management apparatus 100. As a result, work load of the management apparatus 100 increases as the number of electronic devices (management targets) increases. With the modified example 2, the log obtaining process and the log generating process can be decentralized by setting the log transferring apparatus 400 in multiple locations. Thereby, work load of the management apparatus 100B can be reduced. Further, for example, service can be broadly provided by setting the log transferring apparatus 400 in an installation on the side of the user that receives the service and setting the log management apparatus 100B in an installation on the side of a service provider that provides the service.

The present invention is not limited to the specifically disclosed embodiments, and variations and modifications may be made without departing from the scope of the present invention.

The present application is based on Japanese Priority Application Nos. 2012-009940 and 2012-234112 filed on Jan. 20, 2012 and Oct. 23, 2012, respectively, the entire contents of which are hereby incorporated by reference.

What is claimed is:

1. A management apparatus comprising:
an obtaining part configured to obtain a first log data of a first electronic device that is capable of transmitting the first log data;
a generating part configured to generate a second log data of a second electronic device that is unable to transmit the second log data;
a calculating part configured to calculate a first power consumption amount consumed when the first and second electronic devices are used during a predetermined period; and
an outputting part configured to output the power consumption amount calculated by the calculating part.

2. The management apparatus as claimed in claim 1, wherein the generating part is configured to generate the second log data according to a monitor result obtained by monitoring a status of the second electronic device.

3. The management apparatus as claimed in claim 1, further comprising:
an estimating part configured to estimate a second power consumption amount consumed when a substitute electronic device is used instead of the first or the second electronic device during the predetermined period.

4. The management apparatus as claimed in claim 2, wherein the generating part is configured to obtain the status of the second electronic device by calculating an electric current value of the second electronic device.

5. The management apparatus as claimed in claim 1, further comprising:
a log management data storage part configured to store log data including status log data indicating a device status of each of the first and the second electronic devices and operation log data indicating an device operation of each of the first and the second electronic devices;
wherein in a case where the management apparatus accepts input of a designated period, the calculating part is configured to obtain at least one of the status log data and the operation log data from the storage part and calculate a power consumption amount during the designated period in correspondence with the status log data and in correspondence with the operation log data.

6. The management apparatus as claimed in claim 5, further comprising:
a power consumption management data storage part configured to store power consumption management data including data indicating a type of the log data, and at least one of a data indicating power consumption amount per time relative to the device status and data indicating a power consumption amount per process relative to the device operation;
wherein the calculating part is configured to obtain the data indicating power consumption amount per time relative to the device status from the power consumption management data storage part based on the data indicating the type of the log data, and calculate the power consumption amount during the designated period in correspondence with the status log data based on the obtained data indicating power consumption amount per time relative to the device status and the designated period.

7. The management apparatus as claimed in claim 6, wherein the calculating part is configured to obtain the data indicating power consumption amount per time relative to the operation status from the power consumption management data storage part based on the data indicating the type of the log data, and calculate the power consumption amount during the designated period in correspondence with the operation log data based on the obtained data indicating power consumption amount per time relative to the device operation and the designated period.

8. The management apparatus as claimed in claim 3,
further comprising:
a log management data storage part configured to store log data including status log data indicating a device status of each of the first and the second electronic devices and operation log data indicating an device operation of each of the first and the second electronic devices;
wherein in a case where the management apparatus accepts input of a designated period and a substitute data, the estimating part is configured to obtain at least one of the status log data and the operation log data from the storage part, change at least one of the status log data and the operation log data by replacing a target value included at least one of the obtained status log data and the operation log data with a value included in the substitute data, and estimate the second power consumption amount consumed when a substitute electronic device is used instead of the first or the second electronic device during the predetermined period based on at least one of the changed status log data and the operation log data.

9. The management apparatus as claimed in claim 8, wherein the estimating part is configured to estimate the second power consumption amount consumed when a substitute electronic device is used instead of the first or the second electronic device during the predetermined period by instruct the calculating part to calculate at least one of the power consumption amount during the designated period in correspondence with the changed status log data and the power consumption amount during the designated period in correspondence with the changed operation log.

10. The management apparatus as claimed in claim 3, wherein the outputting part is configured to output a proposed data enabling comparison between the first power consumption amount calculated by the calculating part and the second consumption amount estimated by the estimating part.

11. The management apparatus as claimed in claim 10, wherein the proposed data output by the outputting part indicates the comparison in correspondence with a device type of each of the first electronic device, the second electronic device, and the substitute device.

12. The management apparatus as claimed in claim 10, wherein the proposed data output by the outputting part indicates the comparison in correspondence with a time period of use of each of the first electronic device, the second electronic device, and the substitute device.

13. A management system comprising:
a plurality of electronic devices including first and second electronic devices; and
a management apparatus including
an obtaining part configured to obtain a first log data of the first electronic device that is capable of transmitting the first log data,
a generating part configured to generate a second log data of the second electronic device that is unable to transmit the second log data,
a calculating part configured to calculate a first power consumption amount consumed when the first and second electronic devices are used during a predetermined period, and
an outputting part configured to output the power consumption amount calculated by the calculating part.

14. A management system comprising:
a plurality of electronic devices including first and second electronic devices;
a log transferring apparatus including
an obtaining part configured to obtain a first log data of the first electronic device that is capable of transmitting the first log data, and
a generating part configured to generate a second log data of the second electronic device that is unable to transmit the second log data;
a management apparatus including
a log receiving part configured to receiving the first and the second log data from the log transferring apparatus,
a calculating part configured to calculate a first power consumption amount consumed when the first and second electronic devices are used during a predetermined period, and
an outputting part configured to output the power consumption amount calculated by the calculating part.
